(19) United States
(12) Patent Application Publication
(10) Pub. No.: US 2016/0322378 A1
(43) Pub. Date: Nov. 3, 2016

(54) SEMICONDUCTOR MEMORY DEVICE AND METHOD OF MANUFACTURING THE SAME

(71) Applicant: Kabushiki Kaisha Toshiba, Minato-ku (JP)

(72) Inventors: Takayuki ITO, Yokkaichi (JP); Yasunori OSHIMA, Yokkaichi (JP)

(73) Assignee: Kabushiki Kaisha Toshiba, Minato-ku (JP)

(21) Appl. No.: 14/843,194

(22) Filed: Sep. 2, 2015

Related U.S. Application Data
(60) Provisional application No. 62/153,878, filed on Apr. 28, 2015.

(51) Int. Cl. H01L 27/115

(52) U.S. Cl. CPC H01L 27/11582; H01L 27/11568

(57) ABSTRACT

According to an embodiment, a semiconductor memory device comprises a substrate, a plurality of control gate electrodes, a semiconductor layer, a charge accumulation layer, and a contact. The plurality of control gate electrodes are stacked on the substrate. The semiconductor layer has one end thereof connected to the substrate, has as its longer direction a direction perpendicular to the substrate, and faces the plurality of control gate electrodes. The charge accumulation layer is positioned between the control gate electrode and the semiconductor layer. The contact has its lower end connected to the substrate, and is adjacent to the plurality of control gate electrodes via a first insulating layer. Moreover, a boundary of a first surface that faces a lower surface of the control gate electrode and a second surface that faces a lower surface of the first insulating layer, of an upper surface of the substrate is formed continuously.

### CROSS-REFERENCE TO RELATED APPLICATIONS

This application is based upon and claims the benefit of U.S. Provisional Patent Application No. 62/153,878, filed on Apr. 28, 2015, the entire contents of which are incorporated herein by reference.

### FIELD

Embodiments described herein relate to a semiconductor memory device and a method of manufacturing the same.

### BACKGROUND

### Description of the Related Art

A flash memory that stores data by accumulating a charge in a charge accumulation layer, is known. Such a flash memory is connected by a variety of systems such as NAND type or NOR type, and configures a semiconductor memory device. In recent years, increasing of capacity and raising of integration level of such a nonvolatile semiconductor memory device have been proceeding. Moreover, a semiconductor memory device in which memory cells are disposed three-dimensionally (three-dimensional type semiconductor memory device) has been proposed to raise the integration level of the memory.

### BRIEF DESCRIPTION OF THE DRAWINGS

FIG. 1 is a block diagram of a nonvolatile semiconductor memory device according to a first embodiment.

FIG. 2 is a circuit diagram showing a configuration of part of the same nonvolatile semiconductor memory device.

FIG. 3 is a perspective view showing a configuration of part of the same nonvolatile semiconductor memory device.

FIG. 4 is a perspective view showing a configuration of part of the same nonvolatile semiconductor memory device.

FIG. 5 is a cross-sectional view showing a configuration of part of the same nonvolatile semiconductor memory device.

FIG. 6 is a cross-sectional view showing an operation of the same nonvolatile semiconductor memory device.

FIG. 7 is a flowchart showing a method of manufacturing the same nonvolatile semiconductor memory device.

FIG. 8 is a cross-sectional view showing the same method of manufacturing.

FIG. 9 is a cross-sectional view showing the same method of manufacturing.

FIG. 10 is a cross-sectional view showing the same method of manufacturing.

FIG. 11 is a cross-sectional view showing the same method of manufacturing.

FIG. 12 is a cross-sectional view showing the same method of manufacturing.

FIG. 13 is a cross-sectional view showing the same method of manufacturing.

FIG. 14 is a cross-sectional view showing the same method of manufacturing.

FIG. 15 is a cross-sectional view showing the same method of manufacturing.

FIG. 16 is a cross-sectional view showing the same method of manufacturing.

FIG. 17 is a cross-sectional view showing the same method of manufacturing.

FIG. 18 is a cross-sectional view showing the same method of manufacturing.

FIG. 19 is a cross-sectional view showing the same method of manufacturing.

FIG. 20 is a cross-sectional view showing the same method of manufacturing.

FIG. 21 is a flowchart showing a method of manufacturing a nonvolatile semiconductor memory device according to a first comparative example.

FIG. 22 is a cross-sectional view showing the same method of manufacturing.

FIG. 23 is a cross-sectional view showing the same method of manufacturing.

FIG. 24 is a cross-sectional view showing a configuration of part of the same nonvolatile semiconductor memory device.

FIG. 25 is a flowchart showing a method of manufacturing a nonvolatile semiconductor memory device according to a second comparative example.

FIG. 26 is a cross-sectional view showing the same method of manufacturing.

FIG. 27 is a cross-sectional view showing a configuration of part of the same nonvolatile semiconductor memory device.

FIG. 28 is a cross-sectional view showing a configuration of part of a nonvolatile semiconductor memory device according to a second embodiment.

FIG. 29 is a flowchart showing a method of manufacturing the same nonvolatile semiconductor memory device.

FIG. 30 is a cross-sectional view showing the same method of manufacturing.

FIG. 31 is a cross-sectional view showing the same method of manufacturing.

FIG. 32 is a cross-sectional view showing a configuration of part of a nonvolatile semiconductor memory device according to a third embodiment.

FIG. 33 is a cross-sectional view showing a configuration of part of the same nonvolatile semiconductor memory device.

FIG. 34 is a cross-sectional view showing a method of manufacturing the same nonvolatile semiconductor memory device.

FIG. 35 is a cross-sectional view showing the same method of manufacturing.

FIG. 36 is a cross-sectional view showing the same method of manufacturing.

FIG. 37 is a cross-sectional view showing the same method of manufacturing.

FIG. 38 is a cross-sectional view showing the same method of manufacturing.

FIG. 39 is a cross-sectional view showing the same method of manufacturing.

### DETAILED DESCRIPTION

A semiconductor memory device according to an embodiment comprises a substrate, a plurality of control gate electrodes, a semiconductor layer, a charge accumulation layer, and a contact. The plurality of control gate electrodes are stacked on the substrate. The semiconductor layer has one end thereof connected to the substrate, has as its longer direction a direction perpendicular to the substrate, and faces the plurality of control gate electrodes. The charge accumulation layer is positioned between the control gate electrode and the semiconductor layer. The contact has its lower end connected to the substrate, and is adjacent to the plurality of control gate electrodes via a first insulating layer. Moreover, a boundary of a first surface that faces a lower surface of the control gate electrode and a second surface that faces a lower surface of the first insulating layer, of an upper surface of the substrate is formed continuously.

Next, nonvolatile semiconductor memory devices according to embodiments will be described in detail with reference to the drawings. Note that these embodiments are merely examples, and are not shown with the intention of limiting the present invention. Moreover, each of the drawings of the nonvolatile semiconductor memory devices employed in the embodiments below is schematic, and thicknesses, widths, ratios, and so on, of layers are different from those of the actual nonvolatile semiconductor memory devices.

The embodiments below relate to nonvolatile semiconductor memory devices having a structure in which a plurality of MONOS (Metal-Oxide-Nitride-Oxide-Semiconductor) type memory cells (transistors) are provided in a height direction, each of the MONOS type memory cells including: a semiconductor layer acting as a channel provided in a column shape perpendicularly to a substrate; and a gate electrode layer provided on a side surface of the semiconductor layer via a charge accumulation layer. However, this is also not intended to limit the present invention, and the present invention may be applied also to a memory cell of another form of charge accumulation layer, for example, a SONOS (Semiconductor-Oxide-Nitride-Oxide-Semiconductor) type memory cell, or a floating gate type memory cell, and so on.

### First Embodiment

[Semiconductor Memory Device]

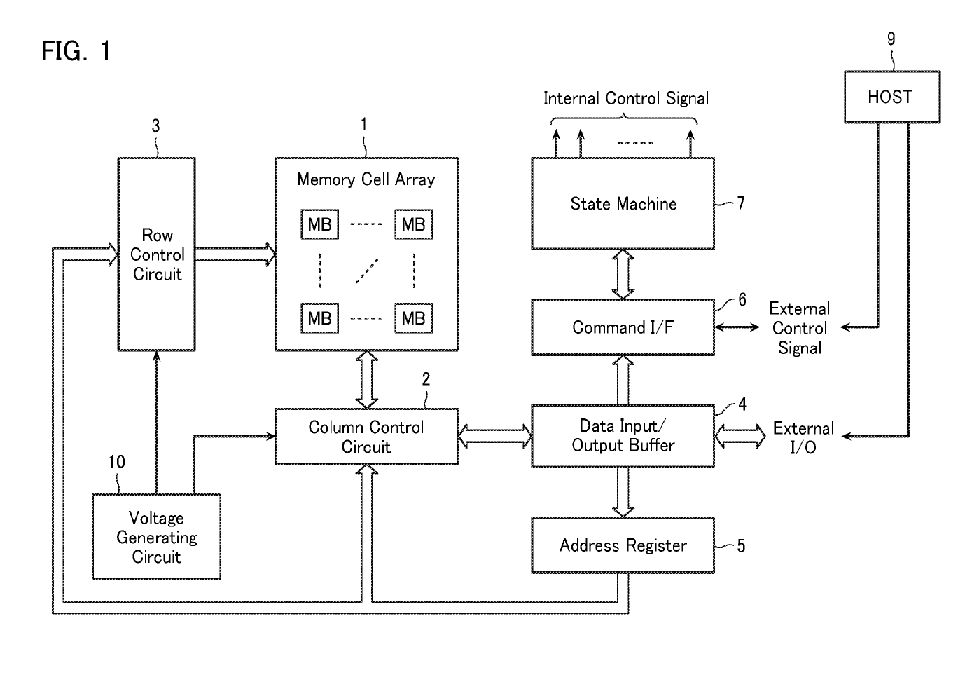

FIG. 1 is a block diagram of a nonvolatile semiconductor memory device according to a first embodiment. The same nonvolatile semiconductor memory device stores write data inputted from an external host 9, in a certain address in a memory cell array 1. In addition, the same nonvolatile semiconductor memory device reads data from a certain address in the memory cell array 1, and outputs the data to the external host 9.

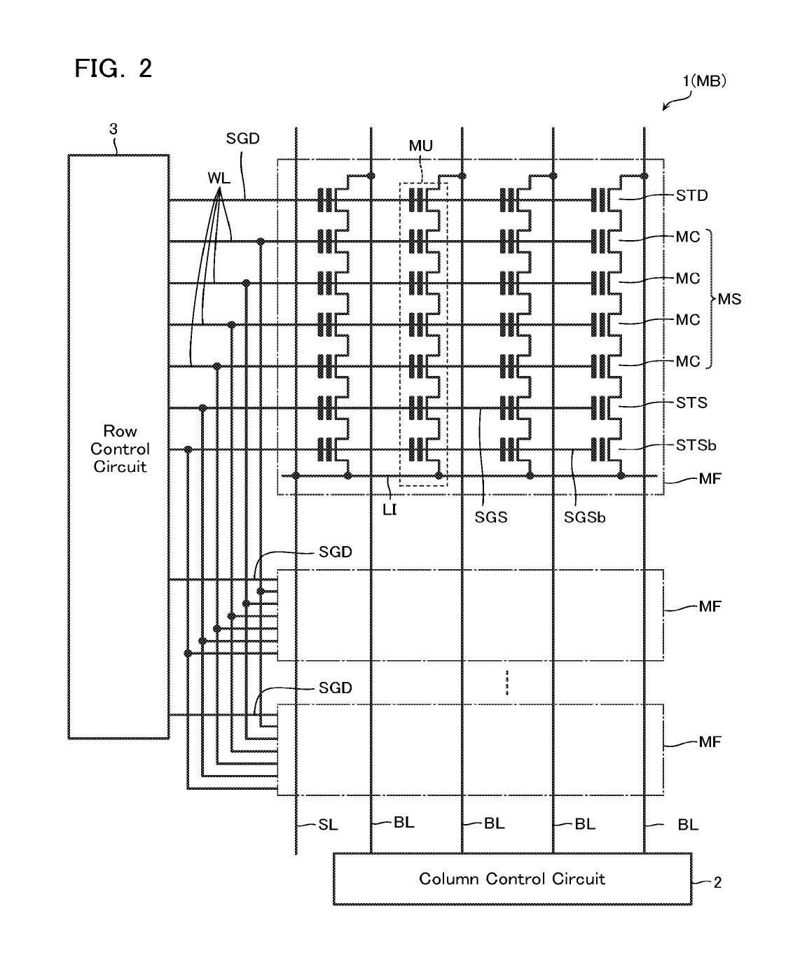

That is, as shown in FIG. 1, the same nonvolatile semiconductor memory device comprises the memory cell array 1 that stores data. The memory cell array 1 comprises a plurality of memory blocks MB. As will be described later with reference to FIG. 2, these memory blocks MB each comprise: a plurality of memory cells MC; and a bit line BL and a word line WL connected to these memory cells MC.

As shown in FIG. 1, the same nonvolatile semiconductor memory device comprises a column control circuit 2 provided in a periphery of the memory cell array 1. The column control circuit 2 transfers a voltage generated by a voltage generating circuit 10 to a desired bit line BL according to inputted data. Moreover, the column control circuit 2 comprises an unillustrated sense amplifier, and detects a voltage or potential of a certain bit line BL.

As shown in FIG. 1, the same nonvolatile semiconductor memory device comprises a row control circuit 3 provided in a periphery of the memory cell array 1. The row control circuit 3 transfers a voltage generated by the voltage generating circuit 10 to a desired word line WL, and so on, according to inputted address data.

As shown in FIG. 1, the same nonvolatile semiconductor memory device comprises an address register 5 that supplies address data to the column control circuit 2 and the row control circuit 3. The address register 5 stores address data inputted from a data input/output buffer 4.

As shown in FIG. 1, the same nonvolatile semiconductor memory device comprises the voltage generating circuit 10 that supplies a voltage to the memory cell array 1 via the column control circuit 2 and the row control circuit 3. The voltage generating circuit 10 generates and outputs a voltage of a certain magnitude at a certain timing, based on an internal control signal inputted from a state machine 7.

As shown in FIG. 1, the same nonvolatile semiconductor memory device comprises the state machine 7 that inputs the internal control signal to the voltage generating circuit 10, and so on. The state machine 7 receives command data from the host 9, via a command interface 6, and performs management of read, write, erase, input/output of data, and so on.

As shown in FIG. 1, the same nonvolatile semiconductor memory device comprises the data input/output buffer 4 which is connected to the external host 9 via an I/O line. The data input/output buffer 4 receives write data from the external host 9, and transfers the write data to the column control circuit 2. Moreover, the data input/output buffer 4 receives command data from the external host 9, and transfers the command data to the command interface 6. In addition, the data input/output buffer 4 receives address data from the external host 9, and transfers the address data to the address register 5. Furthermore, the data input/output buffer 4 receives read data from the column control circuit 2, and transfers the read data to the external host 9.

As shown in FIG. 1, the same nonvolatile semiconductor memory device comprises the command interface 6 that receives an external control signal from the external host 9. The command interface 6 determines which of write data, command data, and address data data inputted to the data input/output buffer 4 is, based on the external control signal inputted from the external host 9, and controls the data input/output buffer 4. In addition, the command interface 6 transfers to the state machine 7 command data received from the data input/output buffer 4.

Note that the column control circuit 2, the row control circuit 3, the state machine 7, the voltage generating circuit 10, and so on, configure a control circuit that controls the memory cell array 1.

Next, a circuit configuration of part of the memory cell array 1 according to the present embodiment will be described with reference to FIG. 2. FIG. 2 is an equivalent circuit diagram showing a configuration of the memory block MB configuring the memory cell array 1. In the memory block MB shown in FIG. 2, a certain drain side select gate line SGD and a certain word line WL are selected by the row control circuit 3, whereby a certain number of memory cells MC are selected. Moreover, data of the memory cells MC connected to a certain number of bit lines BL is read by the column control circuit 2.

As shown in FIG. 2, the memory blocks MB each comprise a plurality of memory fingers MF. Commonly connected to these plurality of memory fingers MF are a plurality of the bit lines BL and a source line SL. Each of the memory fingers MF is connected to the column control circuit 2 via the bit lines BL, and is connected to an unillustrated source line driver via the source line SL.

The memory finger MF comprises a plurality of memory units MU that have their one ends connected to the bit lines BL and have their other ends connected to the source line SL via a source contact LI. The memory units MU included in one memory finger MF are all connected to different bit lines BL.

As shown in FIG. 2, the memory unit MU comprises a plurality of the memory cells MC connected in series. As will be mentioned later, the memory cell MC comprises a semiconductor layer, a charge accumulation layer, and a control gate, and accumulates a charge in the charge accumulation layer based on a voltage applied to the control gate, thereby changing a threshold value of the memory cell MC. Note that hereafter, the plurality of memory cells MC connected in series will be called a “memory string MS”. The row control circuit 3 transfers a voltage to a certain word line WL, thereby transferring this voltage to the control gate of a certain memory cell MC in the memory string MS.

As shown in FIG. 2, commonly connected to the control gates of pluralities of the memory cells MC configuring different memory strings MS are, respectively, the word lines WL. These pluralities of memory cells MC are connected to the row control circuit 3 via the word lines WL. Moreover, in the example shown in FIG. 2, the word lines WL are provided independently to each of the memory cells MC included in the memory unit MU, and are provided commonly for all of the memory units MU included in one memory block MB.

As shown in FIG. 2, the memory unit MU comprises a drain side select gate transistor STD connected between the memory string MS and the bit line BL. Connected to a control gate of the drain side select gate transistor STD is the drain side select gate line SGD. The drain side select gate line SGD is connected to the row control circuit 3, and selectively connects the memory string MS and the bit line BL based on an inputted signal. Moreover, in the example shown in FIG. 2, the drain side select gate line SGD is provided independently to each of the memory fingers MF, and is commonly connected to the control gates of all of the drain side select gate transistors STD in the memory finger MF. The row control circuit 3 selects a certain drain side select gate line SGD, thereby selectively connecting all of the memory strings MS in a certain memory finger MF to the bit lines BL.

Moreover, as shown in FIG. 2, the memory unit MU comprises a source side select gate transistor STS and a lowermost layer source side select gate transistor STSb that are connected between the memory string MS and the source contact LI. Connected to a control gate of the source side select gate transistor STS is a source side select gate line SGS. In addition, connected to a control gate of the lowermost layer source side select gate transistor STSb is a lowermost layer source side select gate line SGSb. Moreover, in the example shown in FIG. 2, the source side select gate line SGS is commonly connected to all of the source side select gate transistors STS in the memory block MB. Similarly, the lowermost layer source side select gate line SGSb is commonly connected to all of the lowermost layer source side select gate transistors STSb in the memory block MB. The row control circuit 3 connects all of the memory strings MS in the memory block MB to the source line SL, based on an inputted signal.

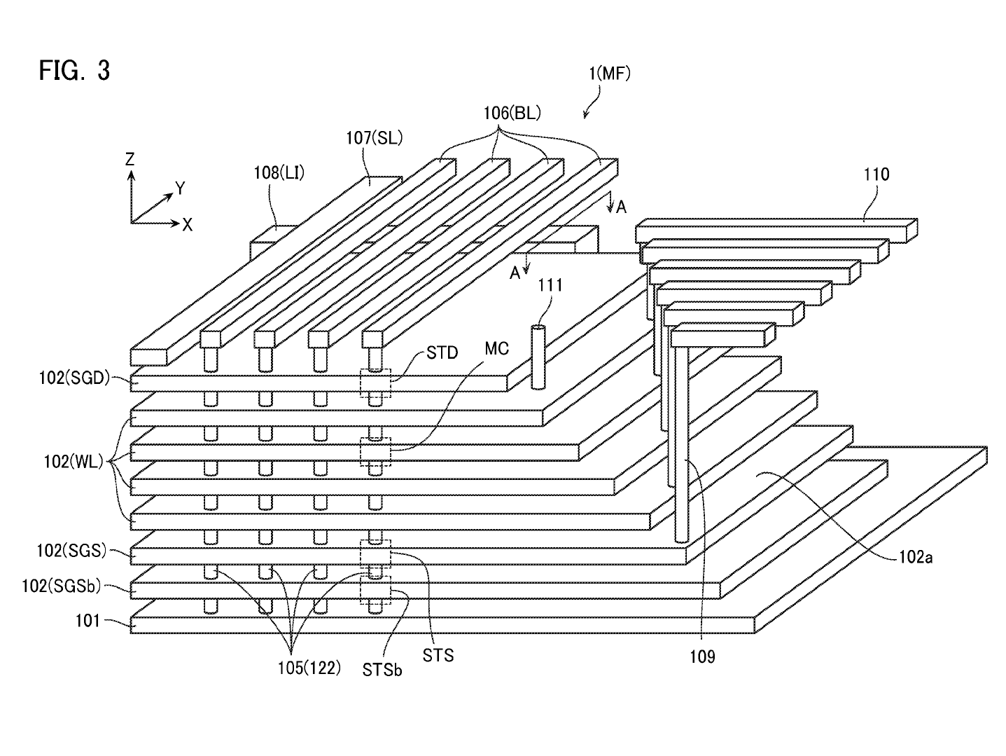

Next, a schematic configuration of the memory cell array 1 will be described with reference to FIG. 3. FIG. 3 is a schematic perspective view showing a configuration of part of the memory finger MF. Note that in FIG. 3, part of the configuration is omitted. Moreover, the configuration shown in FIG. 3 is merely an example, and a specific configuration may be appropriately changed.

As shown in FIG. 3, the memory finger MF comprises: a substrate 101; and a plurality of conductive layers 102 stacked in a Z direction on the substrate 101. In addition, the memory finger MF includes a plurality of memory columnar bodies 105 extending in the Z direction. As shown in FIG. 3, an intersection of the conductive layer 102 and the memory columnar body 105 functions as the lowermost layer source side select gate transistor STSb, the source side select gate transistor STS, the memory cell MC, or the drain side select gate transistor STD. The conductive layer 102 is configured from a conductive layer of the likes of tungsten (W) or polysilicon, for example, and functions as each of the word line WL and control gate electrode of the memory cell MC, the source side select gate line SGS and control gate electrode of the source side select gate transistor STS, the drain side select gate line SGD and control gate electrode of the drain side select gate transistor STD, or the lowermost layer source side select gate line SGSb and control gate electrode of the lowermost layer source side select gate transistor STSb.

As shown in FIG. 3, the plurality of conductive layers 102 are formed in steps, at their ends in an X direction. That is, the conductive layer 102 comprises a contact portion 102a that does not face a lower surface of the conductive layer 102 positioned in a layer above it. Moreover, the conductive layer 102 is connected to a via contact wiring line 109 at this contact portion 102a. Moreover, a wiring line 110 is provided at an upper end of the via contact wiring line 109. Note that the via contact wiring line 109 and the wiring line 110 are configured from a conductive layer of the likes of tungsten.

In addition, as shown in FIG. 3, the memory finger MF comprises a support 111. The support 111 communicates with holes provided in the plurality of conductive layers 102. The support 111 supports a posture of an unillustrated insulating layer provided between the conductive layers 102, in a manufacturing step.

In addition, as shown in FIG. 3, the memory finger MF comprises a conductive layer 108. The conductive layer 108 faces side surfaces in a Y direction of the plurality of conductive layers 102, and has a plate-like shape extending in the X direction and the Z direction. That is, the conductive layer 108 has the X direction as its longer direction in the XY plane, and has the Z direction as its longer direction in the YZ plane. Moreover, in the present embodiment, a width in the X direction of the conductive layer 108 is larger than a width in the Z direction of the conductive layer 108. A lower end of the conductive layer 108 contacts the substrate 101. The conductive layer 108 is configured from a conductive layer of the likes of tungsten (W), for example, and functions as the source contact LI.

In addition, as shown in FIG. 3, the memory finger MF comprises a plurality of conductive layers 106 and a conductive layer 107 that are positioned above the plurality of conductive layers 102 and memory columnar bodies 105, are arranged in plurality in the X direction, and extend in the Y direction. The memory columnar bodies 105 are respectively connected to lower surfaces of the conductive layers 106. The conductive layer 106 is configured from a conductive layer of the likes of tungsten (W), for example, and functions as the bit line BL. Moreover, the conductive layer 108 is connected to a lower surface of the conductive layer 107. The conductive layer 107 is configured from a conductive layer of the likes of tungsten (W), for example, and functions as the source line SL.

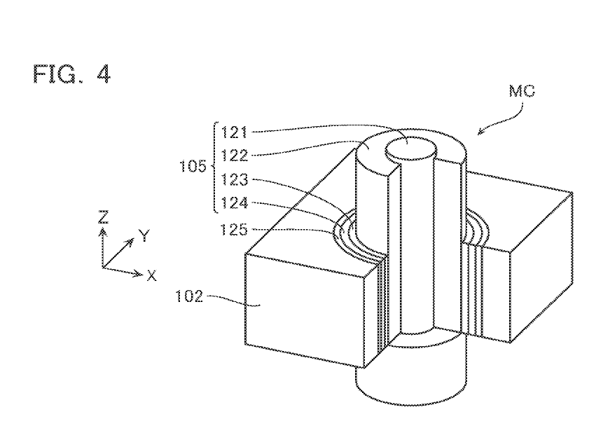

Next, a schematic configuration of the memory cell MC will be described with reference to FIG. 4. FIG. 4 is a schematic perspective view showing the configuration of the memory cell MC. Note that FIG. 4 shows the configuration of the memory cell MC, but the lowermost layer source side select gate transistor STSb, the source side select gate transistor STS, and the drain side select gate transistor STD may also be configured similarly to the memory cell MC. Note that in FIG. 4, part of the configuration is omitted.

As shown in FIG. 4, the memory cell MC is provided at an intersection of the conductive layer 102 and the memory columnar body 105. The memory columnar body 105 comprises: a core insulating layer 121; and a semiconductor layer 122, a tunnel insulating layer 123, and a charge accumulation layer 124 that are stacked on a sidewall of the core insulating layer 121. Furthermore, a block insulating layer 125 is provided between the memory columnar body 105 and the conductive layer 102.

The core insulating layer 121 is configured from an insulating layer of the likes of silicon oxide (SiO₂), for example. The semiconductor layer 122 is configured from a semiconductor layer of the likes of polysilicon, for example, and functions as a channel of the memory cell MC, the lowermost layer source side select gate transistor STSb, the source side select gate transistor STS, and the drain side select gate transistor STD. The tunnel insulating layer 123 is configured from an insulating layer of the likes of silicon oxide (SiO₂), for example. The charge accumulation layer 124 is configured from an insulating layer capable of accumulating a charge, of the likes of silicon nitride (SiN), for example. The block insulating layer 125 is configured from an insulating layer of the likes of silicon oxide (SiO₂), for example.

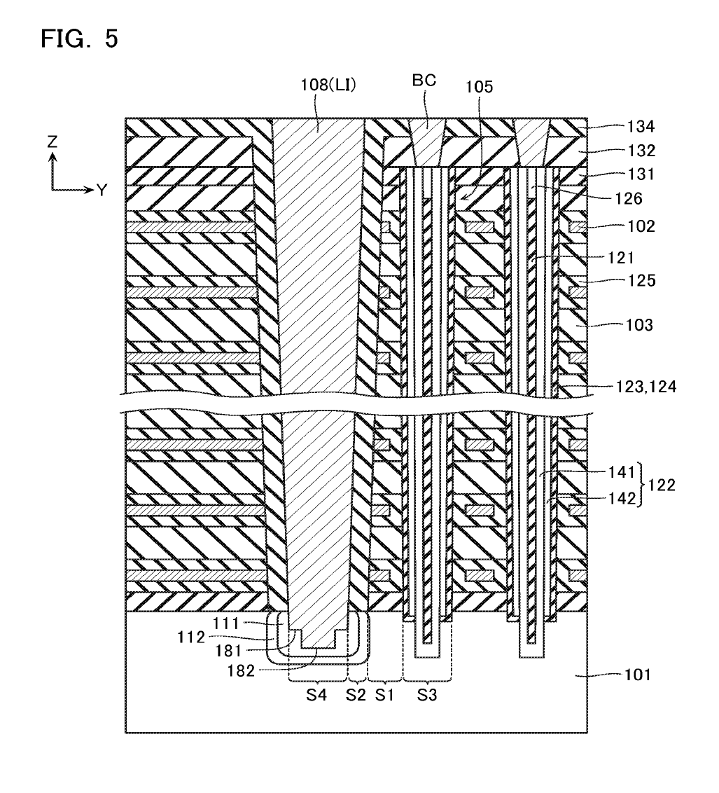

Next, the nonvolatile semiconductor memory device according to the present embodiment will be described in more detail with reference to FIG. 5. FIG. 5 is a cross-sectional view showing a configuration of part of the same nonvolatile semiconductor memory device.

As shown in FIG. 5, the nonvolatile semiconductor memory device according to the present embodiment comprises: the substrate 101; a stacked body including a plurality of the conductive layers 102 and inter-layer insulating layers 103 provided on the substrate 101; the memory columnar body 105 extending in the Z direction; and the conductive layer 108 operating as the source contact LI. In addition, a spacer insulating layer 134 is provided between the conductive layer 108 and the stacked body. Note that the conductive layer 108 may be configured from a single material, or may have a stacked structure configured from a plurality of materials.

As shown in FIG. 5, the stacked body including the plurality of conductive layers 102 and inter-layer insulating layers 103 comprises the block insulating layer 125. The block insulating layer 125 covers an upper surface, a lower surface, and part of a side surface of the conductive layer 102.

As shown in FIG. 5, the memory columnar body comprises: the core insulating layer 121 extending in the Z direction; and a semiconductor layer 141, a semiconductor layer 142, the tunnel insulating layer 123, and the charge accumulation layer 124 that are stacked on the sidewall of the core insulating layer. The semiconductor layer 141 and the semiconductor layer 142 are formed from polysilicon, for example, and configure the semiconductor layer 122 described with reference to FIG. 4. In addition, a conductive layer 126 is implanted in an upper portion of the core insulating layer, and the semiconductor layer 122 is connected to the bit line BL (FIG. 2) via this conductive layer 126 and a bit line contact BC. Moreover, a lower end of the semiconductor layer 141 contacts the substrate 101.

As shown in FIG. 5, a surface S1 facing a lower surface of the conductive layer 102 and a surface S2 facing a lower surface of the spacer insulating layer 134, of the substrate 101 upper surface are formed flat, and a boundary portion of these surface S1 and surface S2 is formed continuously. That is, the surface S1 and the surface S2 contact each other. Note that in the present embodiment, the surface S1 and the surface S2 are parallel to each other, and their positions in the Z direction match. In contrast, a surface S3 facing the memory columnar body 105 and a surface S4 facing the conductive layer 108, of the substrate 101 upper surface have recesses/protrusions formed therein, and heights of these surface S3 and surface S4 are lower compared to heights of the surface S1 and the surface S2. Note that the above-described surface S1 or surface S2 may be a curved surface, not a plane surface.

As shown in FIG. 5, formed in a contact surface with the conductive layer 108, of the substrate 101 are a high concentration impurity diffusion region 111 and a low concentration impurity diffusion region 112. The high concentration impurity diffusion region 111 and the low concentration impurity diffusion region 112 are diffusion regions implanted with an n type impurity, such as phosphorus (P) or arsenic (As), of the substrate 101. Note that another portion (a portion other than the high concentration impurity diffusion region 111 and the low concentration impurity diffusion region 112) of the substrate 101 is implanted with a p type impurity. A concentration of impurity in the high concentration impurity diffusion region 111 is larger than a concentration of impurity in the low concentration impurity diffusion region 112.

As shown in FIG. 5, the high concentration impurity diffusion region 111 covers an entire contact portion with the conductive layer 108, of the substrate 101. Moreover, the low concentration impurity diffusion region 112 covers the high concentration impurity diffusion region 111, and is formed also close to the surface S1 facing the lower surface of the conductive layer 102, of the substrate 101 (below the boundary of the surface S1 and the surface S2).

As shown in FIG. 5, formed at a lower end of the conductive layer 108 are a first portion 181 and a second portion 182, the second portion 182 protruding more downwardly than this first portion 181. In the example shown in FIG. 5, the first portion 181 and the second portion 182 have their lower ends formed flat, and form a step difference with each other. Moreover, both side surfaces in the Y direction of the second portion 182 are provided with a pair of the first portions 181. Moreover, close to a boundary of the first portion 181 and the second portion 182, of a lower surface of the conductive layer 108 is formed in a recessed shape. Therefore, formed at the lower end of the conductive layer 108 are a pair of recessed portions recessed in the Y direction and the Z direction.

[Operation]

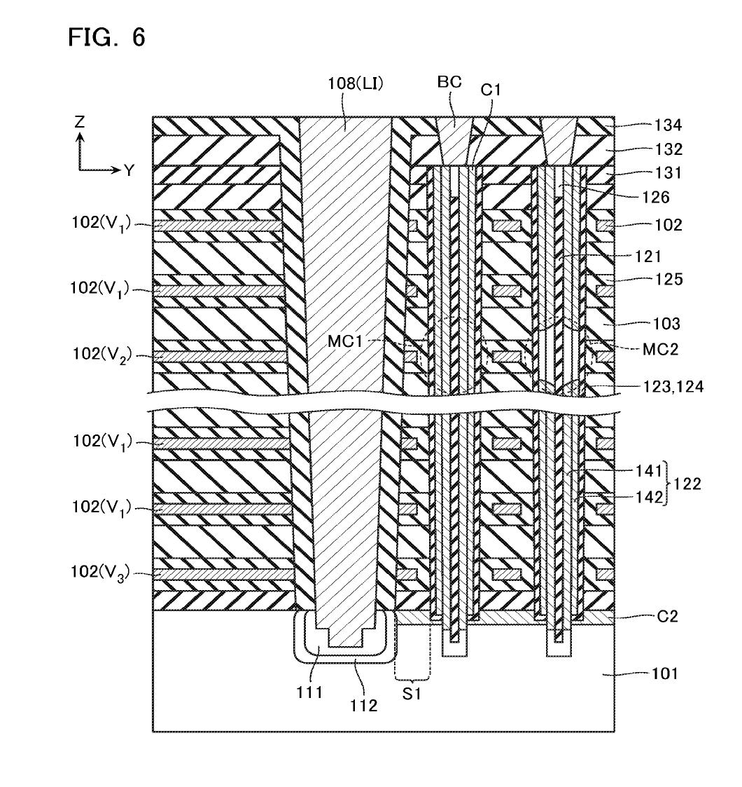

Next, a read operation of the nonvolatile semiconductor memory device according to the present embodiment will be described with reference to FIG. 6. FIG. 6 is a cross-sectional view for explaining the read operation of the nonvolatile semiconductor memory device according to the present embodiment. Note that in the description below, only part of the read operation will be described.

The description below exemplifies the case where the read operation is executed on a memory cell MC1 and a memory cell MC2 in FIG. 6. Hereafter, the memory cell MC which is a target of the read operation will be called a “selected memory cell”, another memory cell MC will be called an “unselected memory cell”, the word line WL connected to the control gate of the selected memory cell will be called a “selected word line”, and the word line WL connected to the control gate of the unselected memory cell will be called an “unselected word line”.

In the read operation according to the present embodiment, the conductive layer 102 operating as the unselected word line is applied with a voltage V₁ such that the memory cell MC attains an ON state. As a result, as shown in FIG. 6, a channel C1 is formed in the semiconductor layer 122 of the unselected memory cell.

Moreover, in the same read operation, the conductive layer 102 operating as the selected word line is applied with a voltage V₂ such that the selected memory cell MC1 in whose charge accumulation layer 124 a charge is not accumulated attains an ON state and the selected memory cell MC2 in whose charge accumulation layer 124 a charge is accumulated attains an OFF state. As a result, as shown in FIG. 6, the channel C1 is formed in the semiconductor layer 122 of the selected memory cell MC1, and a channel is not formed in the semiconductor layer 122 of the selected memory cell MC2.

Moreover, in the same read operation, the conductive layer 102 operating as the lowermost layer source side select gate line SGSb is applied with a voltage V₃. As a result, the lowermost layer source side select gate transistor STSb attains an ON state, and moreover, a channel C2 is formed close to the surface S1 facing the conductive layer 102, of the substrate 101. As a result, as shown in FIG. 6, the source line SL and the bit line BL selectively attain a conductive state via the bit line contact BC, the channel C1, the channel C2, the high concentration impurity diffusion region 111, the low concentration impurity diffusion region 112, and the conductive layer 108. Therefore, for example, a current flows in the bit line BL connected to the selected memory cell MC1, and data “1” is detected. On the other hand, for example, a current does not flow in the bit line BL connected to the selected memory cell MC2, and data “0” is detected.

Note that although the read operation was described as an example here, the high concentration impurity diffusion region 111 or the low concentration impurity diffusion region 112 are connected to the channel C2 also in a write operation or erase operation.

Now, as mentioned above, in the nonvolatile semiconductor memory device according to the present embodiment, the high concentration impurity diffusion region 111 covers the entire contact portion with the conductive layer 108, of the substrate 101. Therefore, forming the n type high concentration impurity diffusion region 111 between the conductive layer 108 and the p type semiconductor substrate 101 results in an NP junction being formed between the conductive layer 108 and the substrate 101, and makes it possible to prevent a leak current from the conductive layer 108 to the substrate 101.

Moreover, in the nonvolatile semiconductor memory device according to the present embodiment, the low concentration impurity diffusion region 112 is formed close to the surface S1 facing the lower surface of the conductive layer 102, of the upper surface of the substrate 101. It is therefore possible to suitably connect the channel C2 and the low concentration impurity diffusion region 112, and thereby suitably operate the nonvolatile semiconductor memory device.

Moreover, as mentioned above, in the nonvolatile semiconductor memory device according to the present embodiment, the boundary portion of the surface S1 facing the lower surface of the conductive layer 102 and the surface S2 facing the lower surface of the spacer insulating layer 134, of the substrate 101 upper surface is formed continuously. As described in detail later, the nonvolatile semiconductor memory device having such a configuration enables the high concentration impurity diffusion region 111 and the low concentration impurity diffusion region 112 having the above-mentioned kinds of distributions to be achieved comparatively easily.

[Method of Manufacturing]

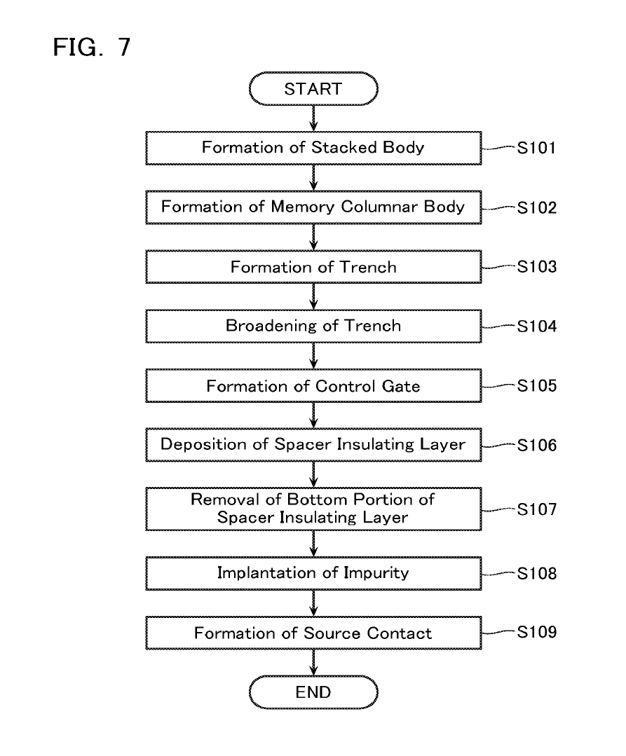

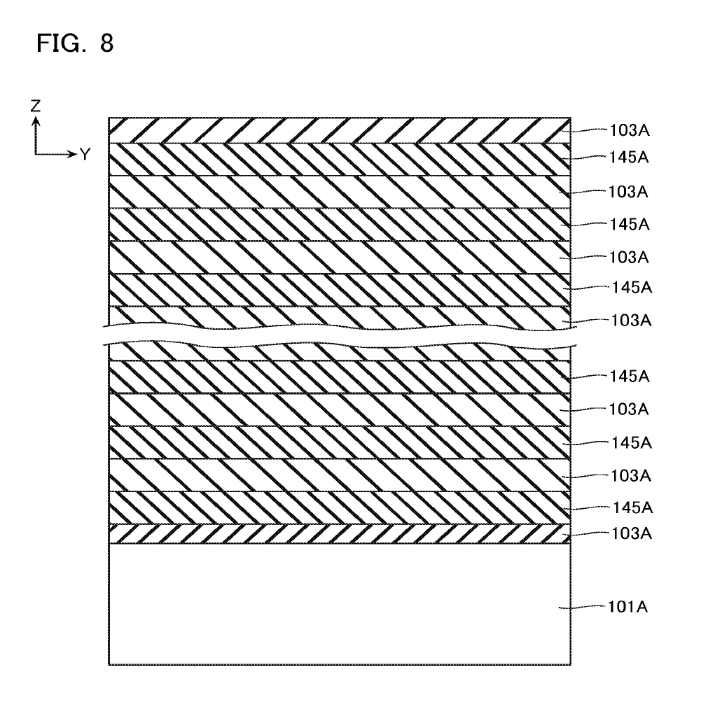

Next, a method of manufacturing a nonvolatile semiconductor memory device according to the first embodiment will be described with reference to FIGS. 7 to 20. FIG. 7 is a flowchart for explaining the same method of manufacturing. FIGS. 8 to 20 are cross-sectional views for explaining the same method of manufacturing.

As shown in FIG. 7, in step S101, a stacked body including a plurality of insulating layers and sacrifice layers is formed on the substrate 101. In step S102, the memory columnar body 105 is formed. In step S103, a trench is formed in the stacked body. In step S104, part of the stacked body is removed via this trench, thereby broadening a width of this trench. In step S105, the sacrifice layer is removed, and the conductive layer 102 operating as the control gate of the memory cell MC, and so on, is formed. Instep S106, an insulating layer which will be the spacer insulating layer 134 is formed. In step S107, a portion positioned on an upper surface of the substrate 101, of this insulating layer is removed to expose the upper surface of the substrate 101 and form the spacer insulating layer 134. In step S108, an impurity is implanted in the exposed upper surface of the substrate 101. In step S109, the conductive layer 108 operating as the source contact LI is formed.

That is, as shown in FIG. 8, in step S101, a stacked body including a plurality of insulating layers 103A and sacrifice layers 145A is formed on a substrate 101A. The insulating layer 103A will be the inter-layer insulating layer 103. In addition, the insulating layer 103A is configured from, for example, silicon oxide (SiO₂). Moreover, the sacrifice layer 145A is configured from, for example, silicon nitride (SiN).

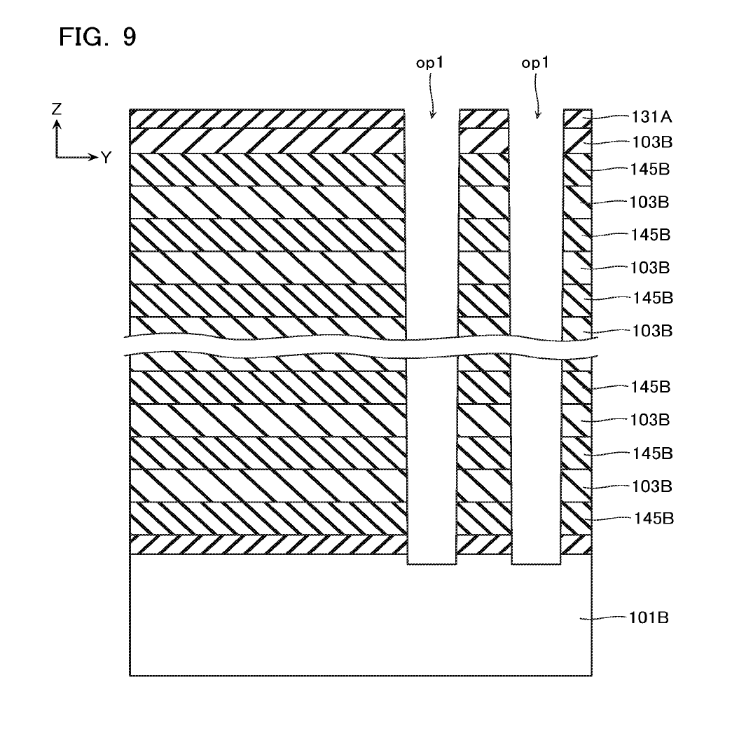

As shown in FIGS. 9 to 12, in step S102, the memory columnar body 105 is formed. That is, as shown in FIG. 9, an insulating layer 131A is formed on the insulating layer 103A. The insulating layer 131A has an opening formed therein, at a position corresponding to the memory columnar body 105. The insulating layer 131A is configured from, for example, silicon oxide (SiO₂). Next, an opening op1 penetrating the insulating layer 103A and the sacrifice layer 145A is formed using this insulating layer 131A as a mask, and an insulating layer 103B and a sacrifice layer 145B that are provided with the opening op1, are formed. Moreover, in this step, an upper surface of a portion corresponding to the opening op1, of a substrate 101A upper surface is removed, and a substrate 101B is formed.

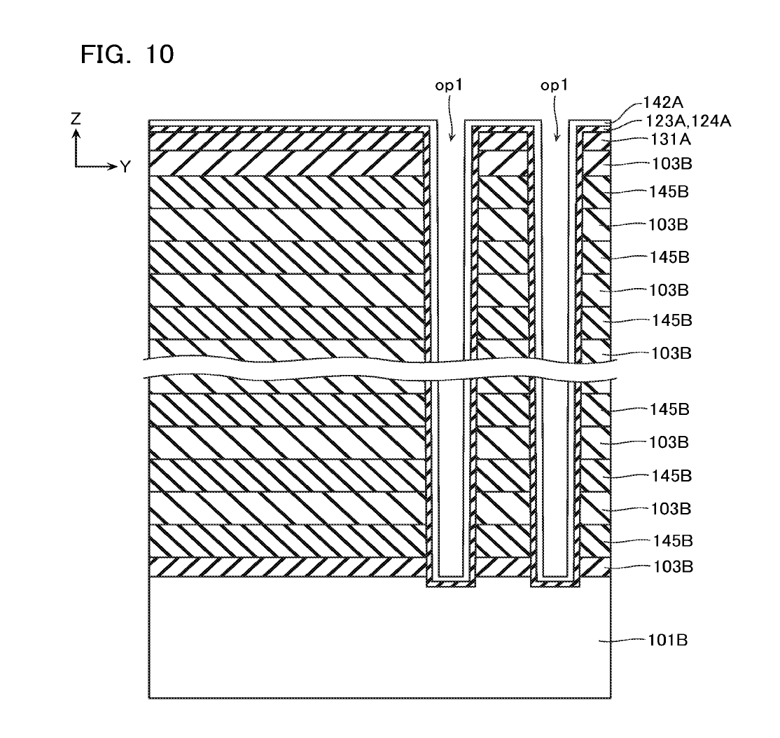

Next, as shown in FIG. 10, a charge accumulation layer formation layer 124A which will be the charge accumulation layer 124, an insulating layer 123A which will be the tunnel insulating layer 123, and a semiconductor layer 142A which will be the semiconductor layer 142, are formed on an inner wall of the opening op1. The charge accumulation layer formation layer 124A is formed from, for example, silicon nitride (SiN). The insulating layer 123A is formed from, for example, silicon oxide (SiO₂). The semiconductor layer 142A is formed from, for example, polysilicon.

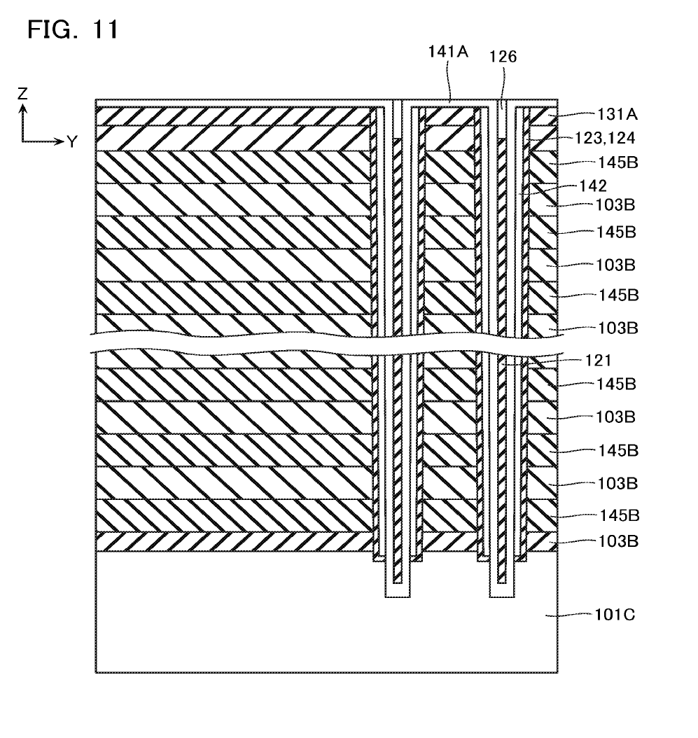

Next, as shown in FIG. 11, portions covering an upper surface of the substrate 101B (portions positioned in a bottom portion of the opening op1) and portions covering an upper surface of the insulating layer 131A, of the charge accumulation layer formation layer 124A, the insulating layer 123A, and the semiconductor layer 142A are removed to expose the upper surface of the substrate 101B. As a result, a substrate 101C, the charge accumulation layer 124, the tunnel insulating layer 123, and the semiconductor layer 142 are formed. Moreover, as shown in FIG. 11, a semiconductor layer 141A which will be the semiconductor layer 141 is formed on the inner wall of the opening op1, the core insulating layer 121 is implanted, and the conductive layer 126 is formed.

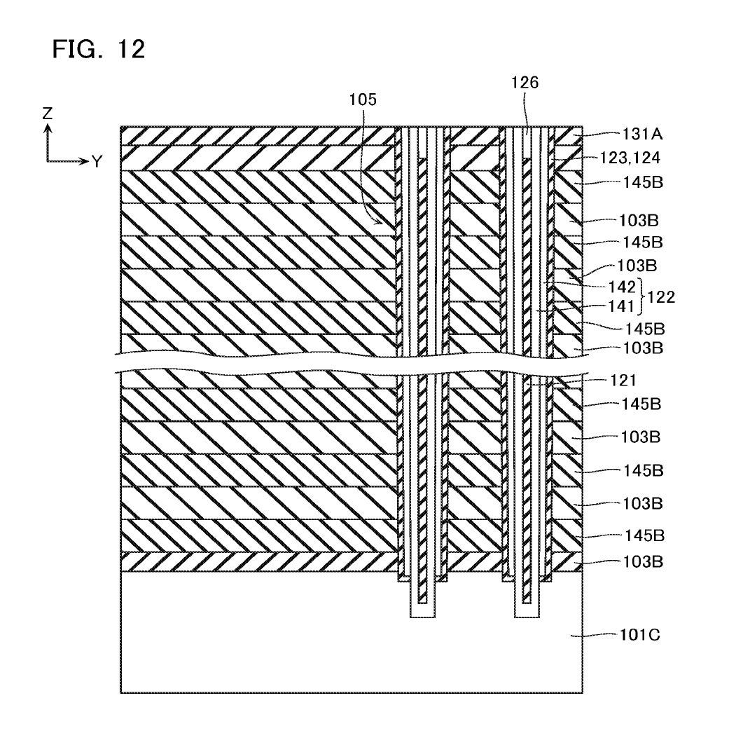

Next, as shown in FIG. 12, a portion covering the upper surface of the insulating layer 131A, of the semiconductor layer 141A is removed to form the semiconductor layer 141. As a result, the memory columnar body 105 is formed.

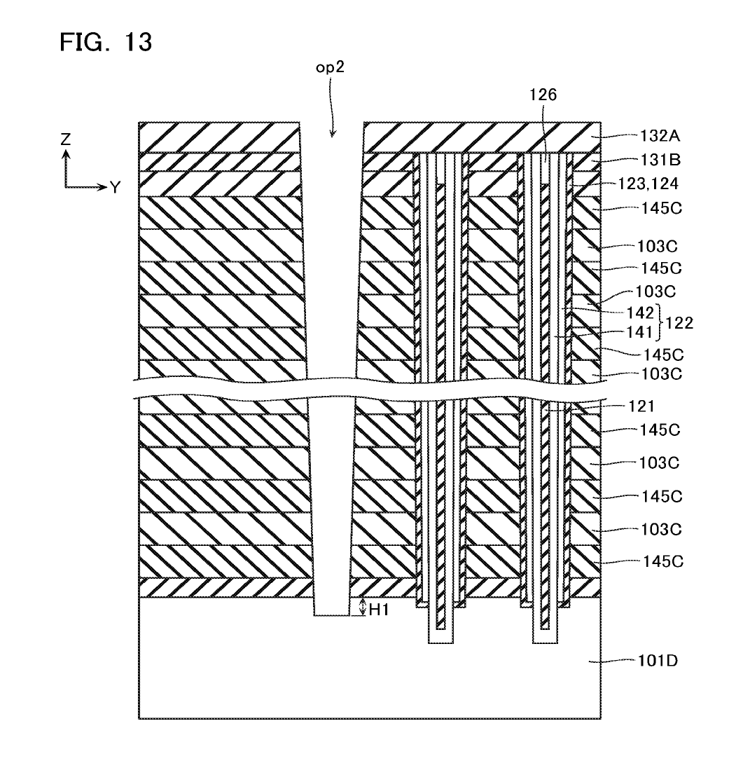

As shown in FIG. 13, in step S103, a trench op2 is formed in the stacked body. For example, as shown in FIG. 13, an insulating layer 132A is formed on the insulating layer 131A. The insulating layer 132A has an opening formed therein, at a position corresponding to the conductive layer 108. The insulating layer 132A is configured from, for example, silicon oxide (SiO₂). Next, the trench op2 dividing the insulating layer 103B, the sacrifice layer 145B, and the insulating layer 131A is formed using this insulating layer 132A as a mask, and an insulating layer 103C, a sacrifice layer 145C, and an insulating layer 131B that are provided with the trench op2, are formed. In this step, an upper surface of a portion corresponding to the trench op2, of a substrate 101C upper surface is removed to an extent of a height H1, and a substrate 101D is formed. Note that formation of the trench op2 is performed by anisotropic dry etching, such as RIE (Reactive Ion Etching), for example. Moreover, in step S103 in the present embodiment, the trench op2 dividing the stacked body in the Y direction is formed, but provided there is an opening penetrating the stacked body, it need not be a trench. For example, a through hole may be formed as this opening.

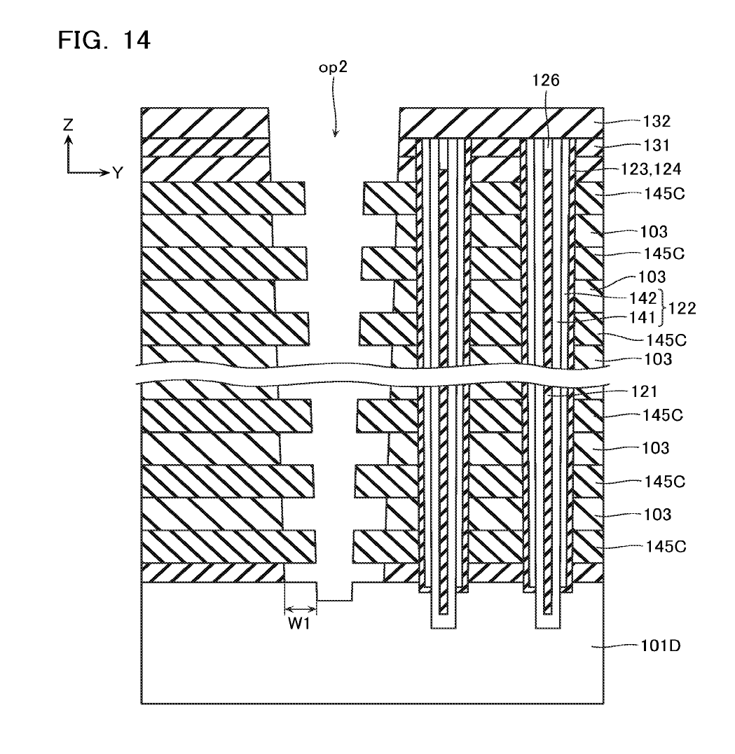

As shown in FIG. 14, in step S104, a width in the Y direction of the trench op2 is broadened. That is, as shown in FIG. 14, part of the insulating layer 103C is removed from the Y direction, via the trench op2. In the example shown in FIG. 14, a portion exposed in the trench op2, of the insulating layer 103C is removed to an extent of a width W1. As a result, the inter-layer insulating layer 103 is formed. Moreover, due to a portion that was covered by the insulating layer 103C, of a substrate 101D upper surface being exposed, a recessed/protruding portion of the substrate 101D upper surface is exposed via the trench op2. This step is performed by the likes of wet etching, for example. Moreover, this step is performed under a condition that the insulating layer 103C is removed sufficiently faster compared to the substrate 101D. For this purpose, it is conceivable to employ the likes of DHF (Diluted Hydrofluoric Acid), for example, as a chemical solution used in the wet etching.

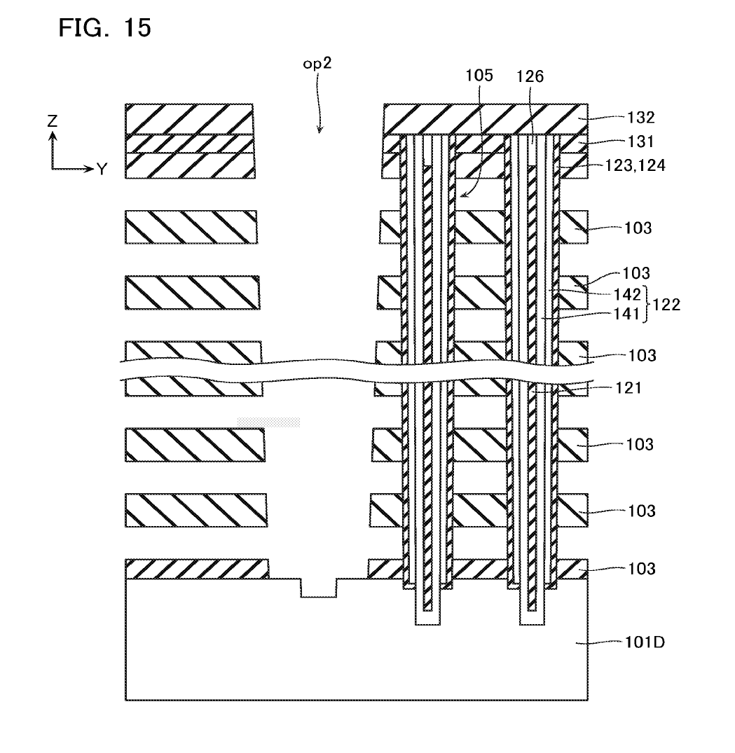

As shown in FIGS. 15 to 17, in step S105, the conductive layer 102 operating as the control gate of the memory cell MC, and so on, is formed. That is, as shown in FIG. 15, the sacrifice layer 145C is removed by the likes of wet etching using phosphoric acid. As a result, as shown in FIG. 15, an upper surface and lower surface of the inter-layer insulating layer 103 and a sidewall of the memory columnar body 105 are exposed.

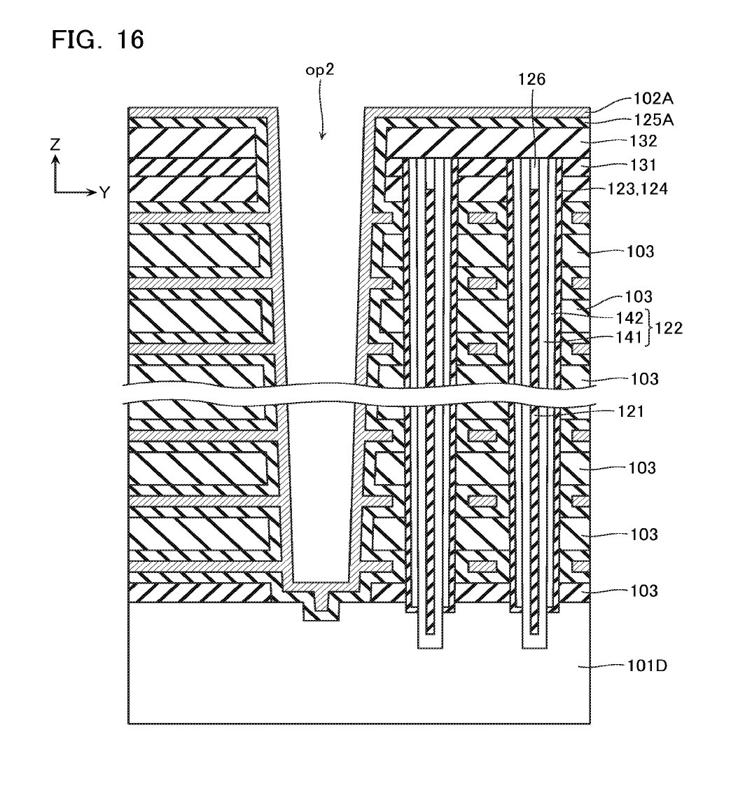

Next, as shown in FIG. 16, an insulating layer 125A which will be the block insulating layer 125 is formed on the upper surface and lower surface of the inter-layer insulating layer 103 and the sidewall of the memory columnar body 105. Moreover, formed in a portion between the inter-layer insulating layers 103 adjacent in a stacking direction is a conductive layer 102A which will be the conductive layer 102.

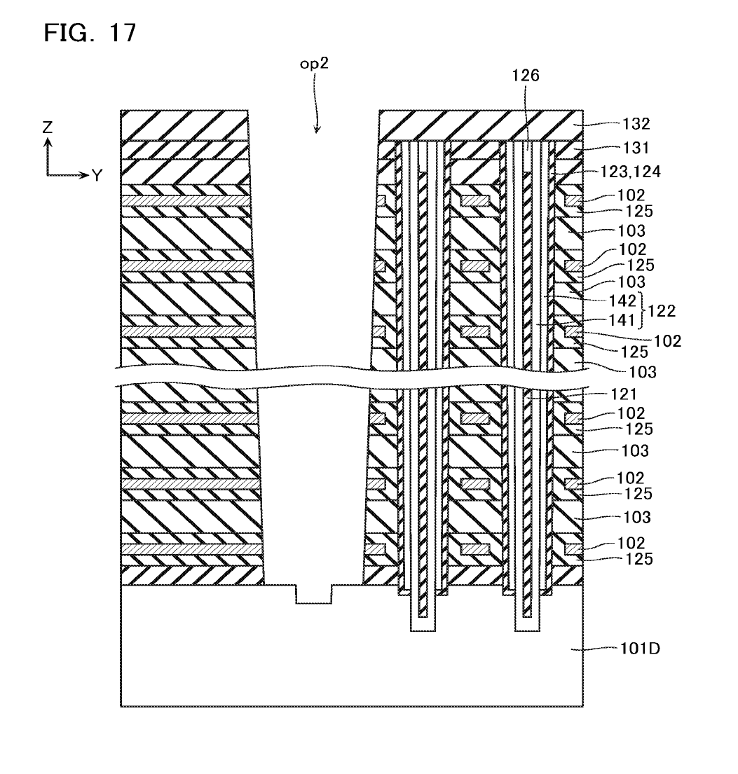

Next, as shown in FIG. 17, portions positioned on an upper surface of the insulating layer 132, portions positioned on a sidewall of the inter-layer insulating layer 103, and portions covering the upper surface of the substrate 101D, of the insulating layer 125A and the conductive layer 102A, are removed. As a result, the block insulating layer 125 and the conductive layer 102 that are divided in the Z direction, are formed.

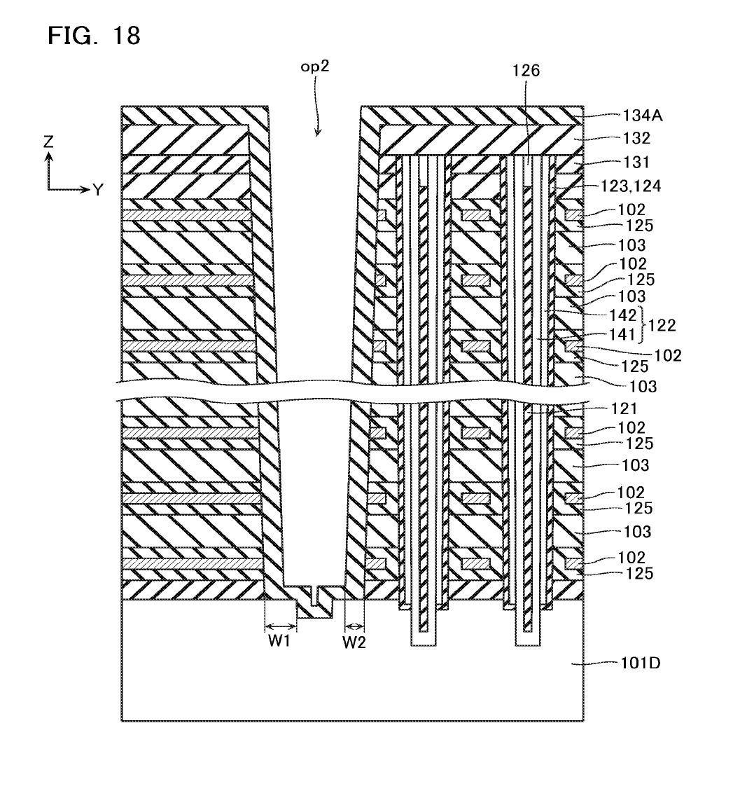

As shown in FIG. 18, in step S106, an insulating layer 134A forming the spacer insulating layer 134, is deposited. The insulating layer 134A is formed by the likes of silicon oxide (SiO₂), for example. Note that a film thickness W2 of the insulating layer 134A may be adjusted so as to be smaller than the width W1 described with reference to FIG. 14, for example.

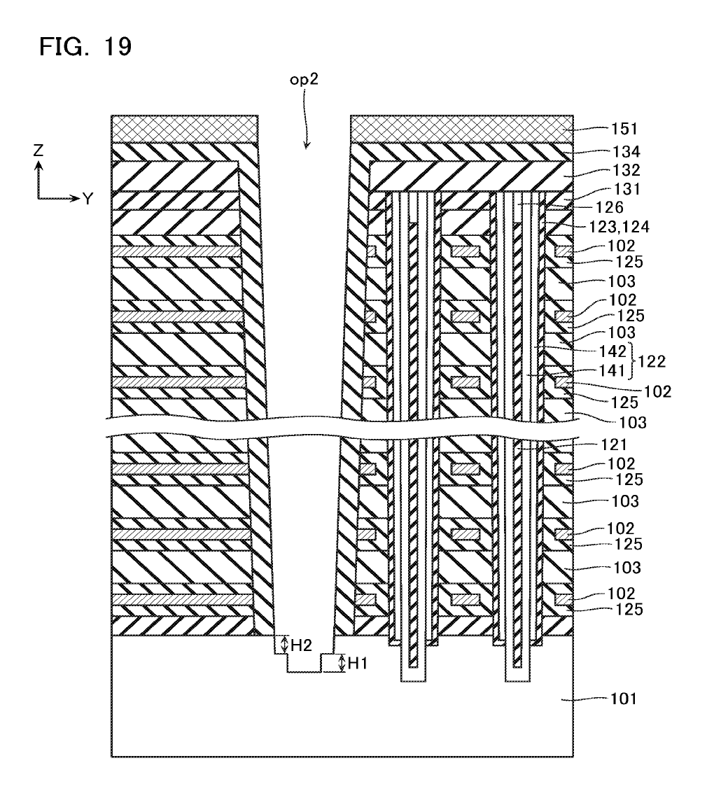

As shown in FIG. 19, in step S107, a portion covering the upper surface of the substrate 101D, of the insulating layer 134A is removed, and the spacer insulating layer 134 is formed. For example, as shown in FIG. 19, a mask 151 is formed on an upper surface of a portion positioned above the conductive layer 102, and so on, of the insulating layer 134A, and anisotropic dry etching such as RIE (Reactive Ion Etching) is performed. In this step, an upper surface of a portion where a bottom portion of the insulating layer 134A is formed, of the substrate 101D upper surface, is removed to an extent of a height H2, and the substrate 101 is formed. At this time, close to a portion removed when forming the trench opt in step S103, of the substrate 101D upper surface (refer to FIG. 13) becomes lower to an extent of the height H1+the height H2 compared to the above-described surface S2, and the above-described second portion 182 of the conductive layer 108 is formed therein. On the other hand, a portion other than the above-described portion, of the removed portion of the substrate 101D upper surface becomes lower to an extent of the height H2 compared to the above-described surface S2, and the above-described first portion 181 of the conductive layer 108 is formed therein. Moreover, a step difference is formed between these portions, and the above-described recessed portion of the conductive layer 108 is formed therein.

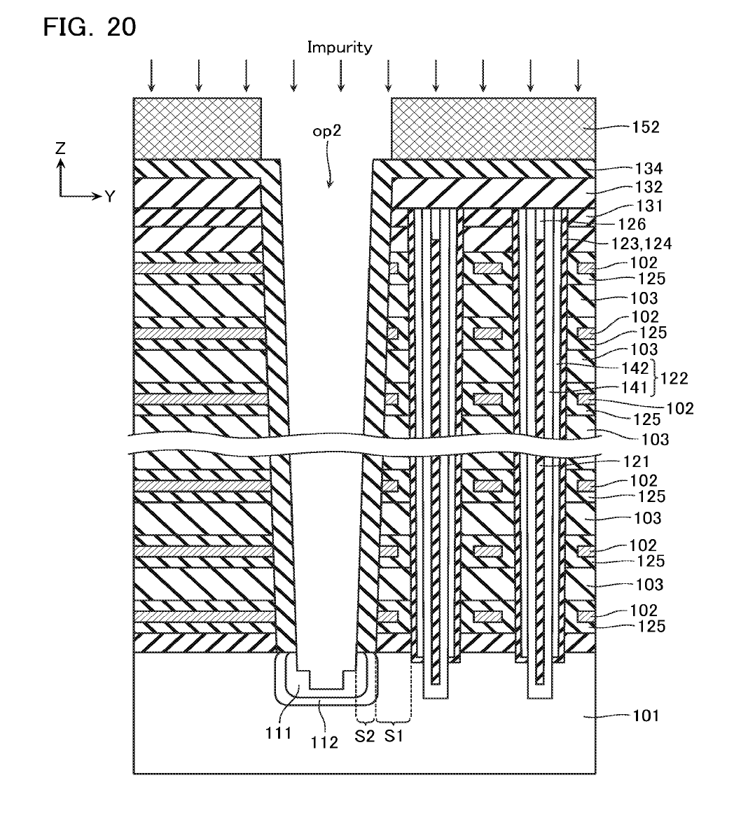

As shown in FIG. 20, in step S108, an impurity is implanted in the substrate 101 via the trench op2, and the high concentration impurity diffusion region 111 and the low concentration impurity diffusion region 112 are formed. For example, a mask 152 is formed on an upper surface of a portion positioned above the conductive layer 102, and so on, of the spacer insulating layer 134, and an n type impurity such as phosphorus (P) or arsenic (As) is implanted. These impurities diffuse inside the substrate 101 from an exposed surface of the substrate 101. Moreover, as shown in FIG. 20, a concentration of impurity is comparatively high at a position close to the exposed surface of the substrate 101, and such a portion becomes the high concentration impurity diffusion region 111. Moreover, a concentration of impurity is comparatively low at a position distant from the exposed surface of the substrate 101, and such a portion becomes the low concentration impurity diffusion region 112.

As shown in FIG. 5, in step S109, the conductive layer 108 operating as the source contact LI is formed in the trench op2.

Then, as shown in FIG. 5, a through hole penetrating the spacer insulating layer 134 and the insulating layer 132 is formed in an upper portion of the memory columnar body 105, and the bit line contact BC is formed therein. As a result, the nonvolatile semiconductor memory device described with reference to FIG. 5 is manufactured.

[Nonvolatile Semiconductor Memory Device According to First Comparative Example]

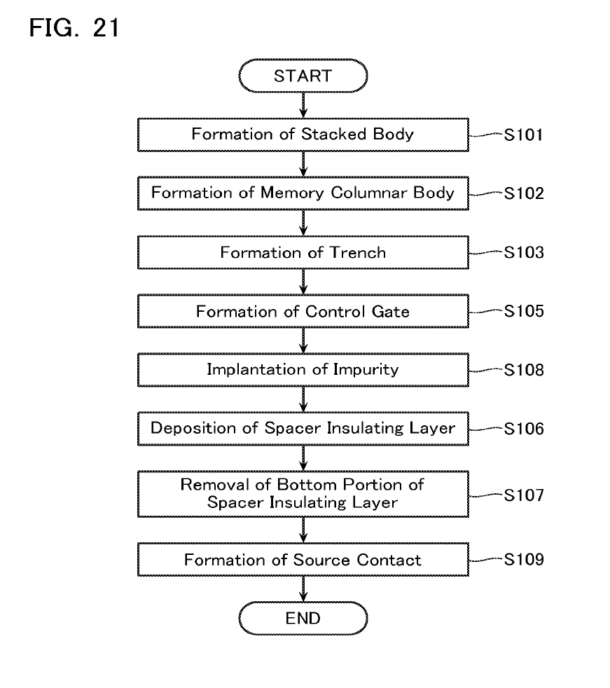

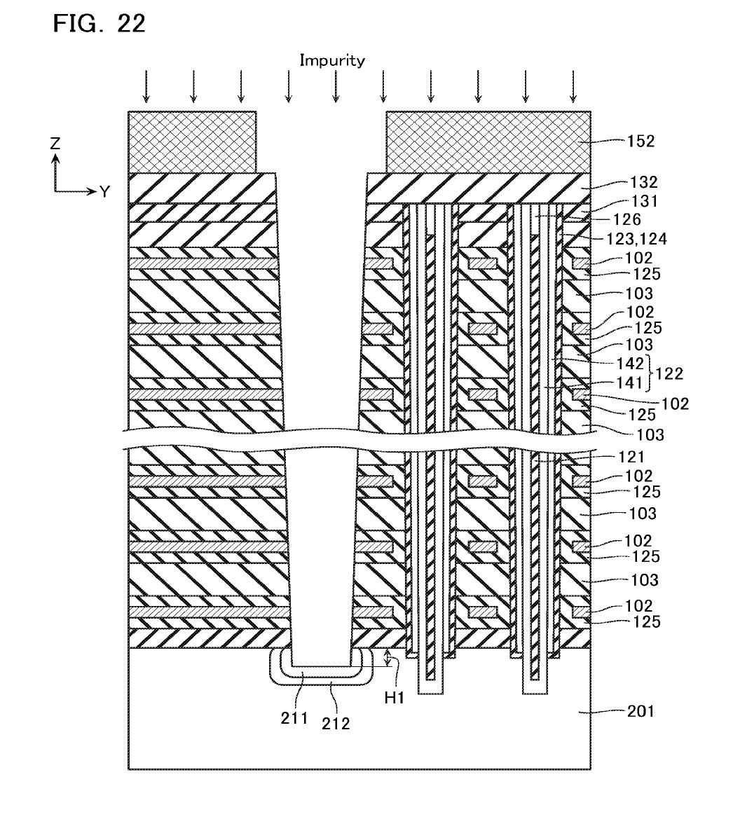

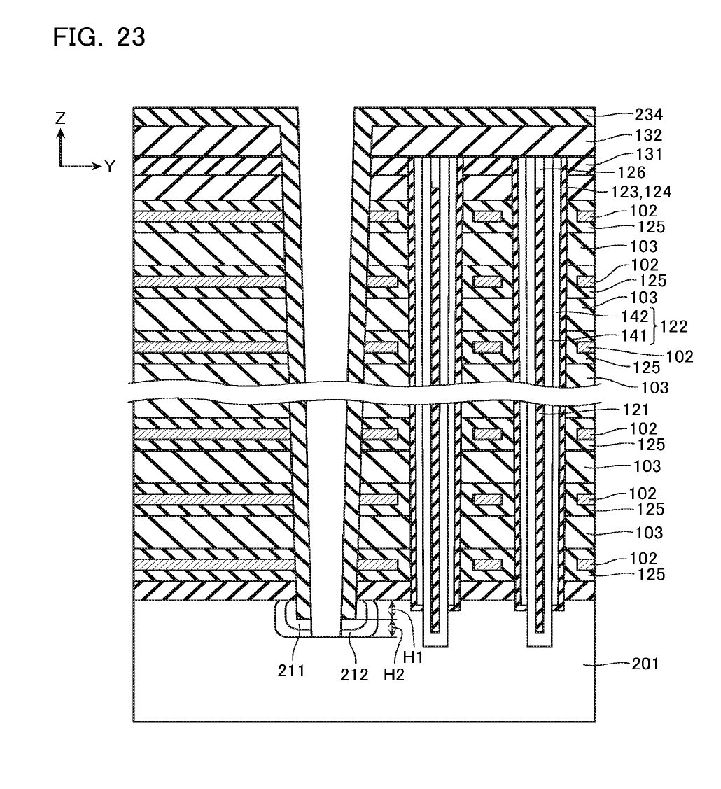

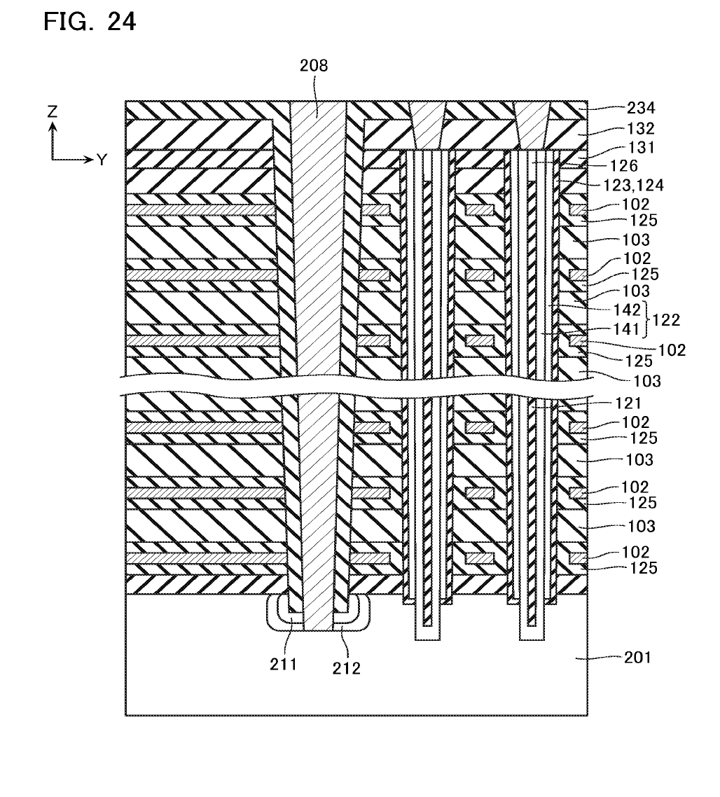

Next, a nonvolatile semiconductor memory device according to a first comparative example will be described with reference to FIGS. 21 to 24. FIG. 21 is a flowchart for explaining a method of manufacturing the same nonvolatile semiconductor memory device. FIGS. 22 and 23 are cross-sectional views for explaining the same method of manufacturing. FIG. 24 is a cross-sectional view for explaining a configuration of the same device. Note that in the description below, portions similar to those of the first embodiment will be assigned with identical reference symbols to those assigned in the first embodiment, and descriptions thereof will be omitted.

As shown in FIG. 21, the nonvolatile semiconductor memory device according to the first comparative example is basically manufactured similarly to the nonvolatile semiconductor memory device according to the first embodiment. However, the method of manufacturing according to the first comparative example does not include a step of what is referred to in the method of manufacturing according to the first embodiment as broadening the trench (step S104).

Moreover, as shown in FIGS. 21 and 22, in step S105, the control gate of the memory cell MC, and so on, is formed, and then in step S108, implantation of the impurity is performed, and a high concentration impurity diffusion region 211 and a low concentration impurity diffusion region 212 are formed.

Furthermore, as shown in FIGS. 21 and 23, in step S106, the insulating layer which will be the spacer insulating layer is deposited, and in step S107, part of the insulating layer is removed, and a spacer insulating layer 234 is formed. At this time, as shown in FIG. 23, an upper surface of a substrate 201 is removed to an extent of the height H2. As a result, sometimes, as shown in FIG. 23, part of the high concentration impurity diffusion region 211 is removed, and the low concentration impurity diffusion region 212, or a portion where the n type impurity is not present, of the substrate 201, are exposed.

As shown in FIG. 24, when the nonvolatile semiconductor memory device is manufactured by such a method of manufacturing, a bottom portion of a conductive layer 208 operating as the source contact LI ends up contacting the low concentration impurity diffusion region 212, or the portion where the n type impurity is not present, of the substrate 201. As a result, a leak current sometimes ends up occurring between the conductive layer 208 and the substrate 201.

[Nonvolatile Semiconductor Memory Device According to Second Comparative Example]

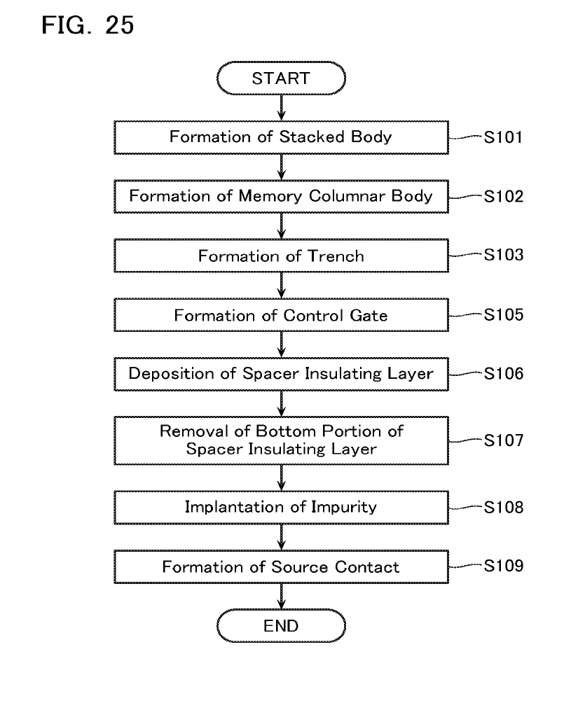

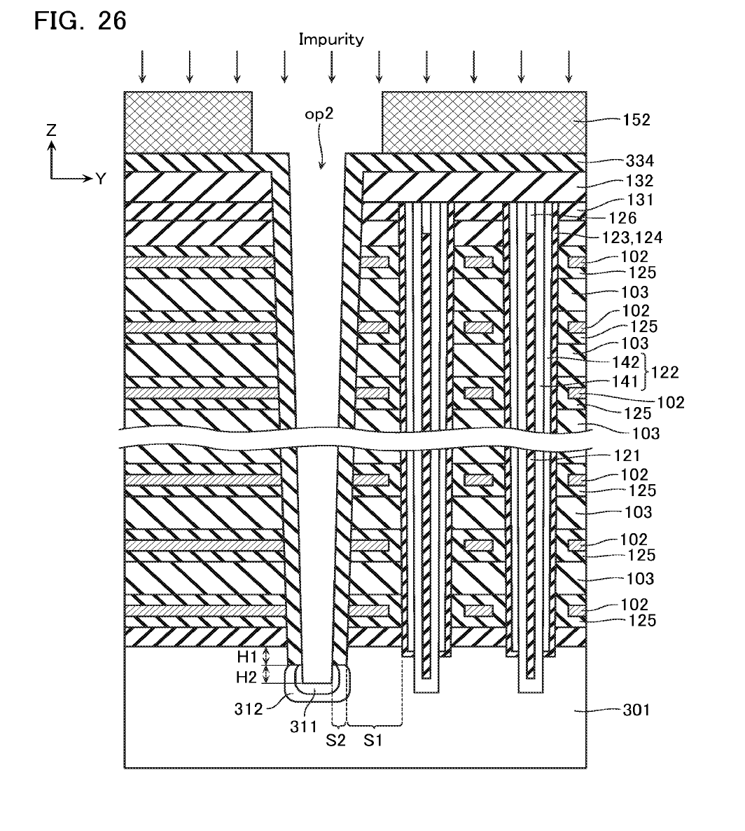

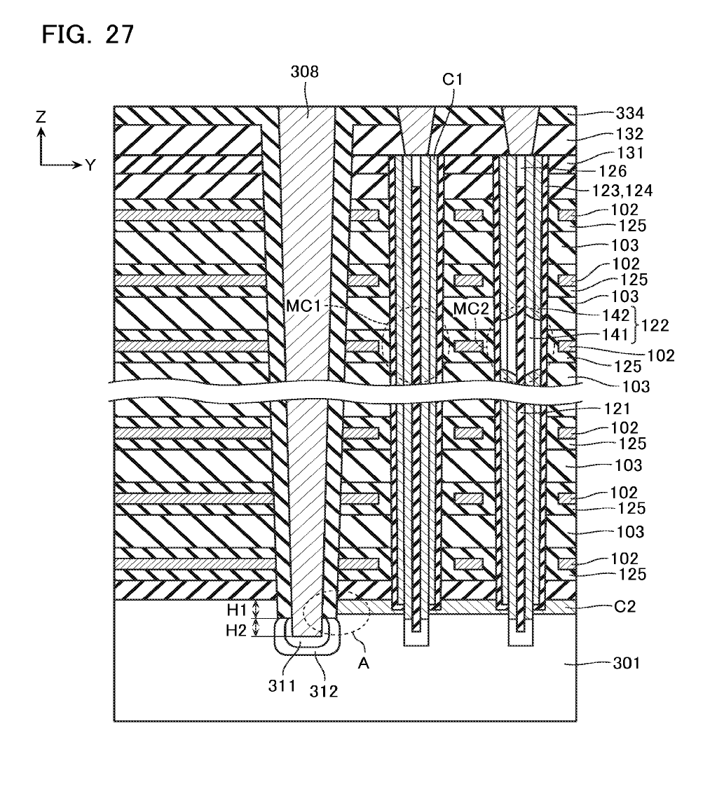

Next, a nonvolatile semiconductor memory device according to a second comparative example will be described with reference to FIGS. 25 to 27. FIG. 25 is a flowchart for explaining a method of manufacturing the same nonvolatile semiconductor memory device. FIG. 26 is a cross-sectional view for explaining the same method of manufacturing. FIG. 27 is a cross-sectional view for explaining a configuration and an operation of the same device. Note that in the description below, portions similar to those of the first embodiment will be assigned with identical reference symbols to those assigned in the first embodiment, and descriptions thereof will be omitted.

As shown in FIG. 25, the nonvolatile semiconductor memory device according to the second comparative example is basically manufactured similarly to the nonvolatile semiconductor memory device according to the first comparative example. However, in the method of manufacturing according to the second comparative example, a step of implanting the impurity (step S108) is performed after steps of forming a spacer insulating layer 334 (steps S106 and S107), not before the steps of forming the spacer insulating layer 334, and in this respect the method of manufacturing according to the second comparative example differs from that according to the first comparative example.

That is, as shown in FIG. 26, the method of manufacturing according to the second comparative example also has an upper surface of a substrate 301 partly removed when removing the bottom portion of the insulating layer forming the spacer insulating layer. However, in the method of manufacturing according to the second comparative example, the impurity is implanted after this, hence a high concentration impurity diffusion region 311 is not removed. Therefore, as shown in FIG. 27, an entire contact portion with a conductive layer 308, of the substrate 301 can be suitably covered by the high concentration impurity diffusion region 311. Therefore, an NP junction is formed between the conductive layer 308 and the substrate 301, and a leak current from the conductive layer 308 to the substrate 301 can be prevented.

However, as shown in FIG. 26, in the method of manufacturing according to the second comparative example, in step S103, the upper surface of the substrate 301 is removed to an extent of H1 when forming the trench op2, and in steps S106 and S107, the spacer insulating layer 334 gets formed therein. Therefore, as shown in FIG. 26, in step S108, when implanting the impurity in the upper surface of the substrate 301, a step difference of the height H1 is formed between the surface S1 facing the lower surface of the conductive layer 102 and the surface S2 facing the lower surface of the spacer insulating layer 334, of the substrate 301 upper surface, and the surface S1 and the surface S2 get formed discontinuously. Therefore, when the impurity is implanted below the surface S2 from a surface exposed to the trench op2 of the substrate 301, a low concentration impurity diffusion region 312 gets formed at a position downwardly distant from the surface S1. Therefore, sometimes, as shown in FIG. 27, when the channel C2 is formed in the substrate 301 upper surface during the read operation, and so on, this channel C2 and the low concentration impurity diffusion region 312 cannot be suitably connected.

[Comparison of Methods of Manufacturing]

As mentioned above, in the method of manufacturing a nonvolatile semiconductor memory device according to the first embodiment, contrary to in the first comparative example, the step of implanting the impurity (step S108) is performed after the steps of forming the spacer insulating layer 134 (steps S106 and S107). Therefore, as shown in FIG. 5, the entire contact portion with the conductive layer 108, of the substrate 101 can be covered by the high concentration impurity diffusion region 111. Therefore, an NP junction is formed between the conductive layer 108 and the substrate 101, and a leak current from the conductive layer 108 to the substrate 101 can be prevented.

Moreover, as mentioned above, in the method of manufacturing a nonvolatile semiconductor memory device according to the first embodiment, contrary to in the second comparative example, the trench is formed in the stacked body in step S103 (refer to FIG. 13), and then, in step S104, part of the stacked body is removed via this trench, thereby broadening the width of this trench (refer to FIG. 14). Moreover, in steps S106 and S107, the spacer insulating layer 134 is formed in a portion where this trench has been broadened (refer to FIGS. 18 and 19). Therefore, as shown in FIG. 20, when implanting the impurity in the upper surface of the substrate 101 in step S108, the surface S1 facing the lower surface of the conductive layer 102 and the surface S2 facing the lower surface of the spacer insulating layer 134, of the substrate 101 upper surface are formed continuously. Therefore, implanting the impurity below the surface S2 from a surface exposed to the trench opt of the substrate 101 makes it possible for the low concentration impurity diffusion region 112 to be provided close to the surface S1. It is therefore possible to manufacture a nonvolatile semiconductor memory device in which the channel C2 (refer to FIG. 6) and the low concentration impurity diffusion region 112 can be suitably connected.

### Second Embodiment

[Semiconductor Memory Device]

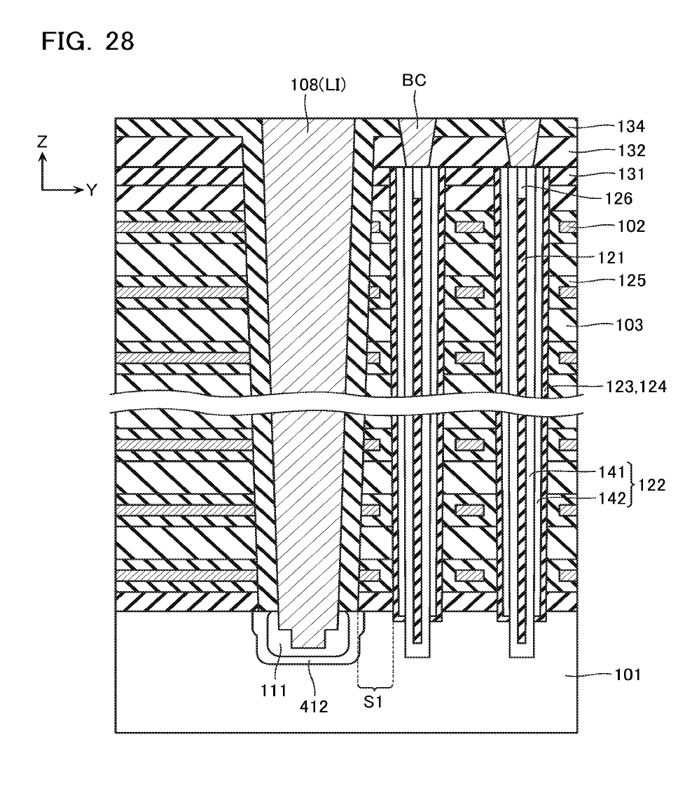

Next, a configuration of a nonvolatile semiconductor memory device according to a second embodiment will be described with reference to FIG. 28. FIG. 28 is a cross-sectional view for explaining the configuration of the nonvolatile semiconductor memory device according to the second embodiment. Note that in the description below, portions similar to those of the first embodiment will be assigned with identical reference symbols to those assigned in the first embodiment, and descriptions thereof will be omitted.

As shown in FIG. 28, the nonvolatile semiconductor memory device according to the present embodiment is basically configured similarly to the nonvolatile semiconductor memory device according to the first embodiment, but has a mode of a low concentration impurity diffusion region 412 which is different. That is, as shown in FIG. 28, in the second embodiment, the low concentration impurity diffusion region 412 is provided also on the surface S1 facing the conductive layer 102 of the substrate 101 upper surface. Therefore, the channel C2 (FIG. 6) and the low concentration impurity diffusion region 412 can be more suitably connected during the operation.

[Method of Manufacturing]

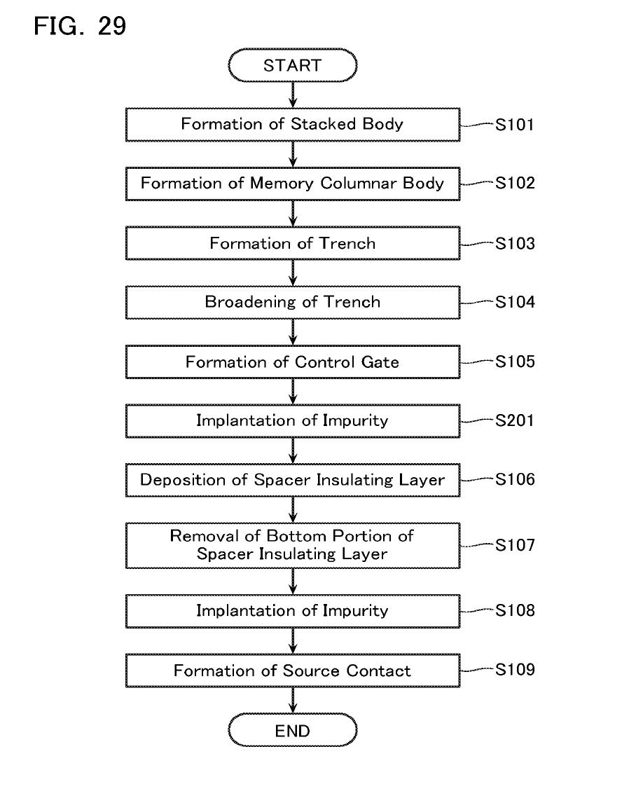

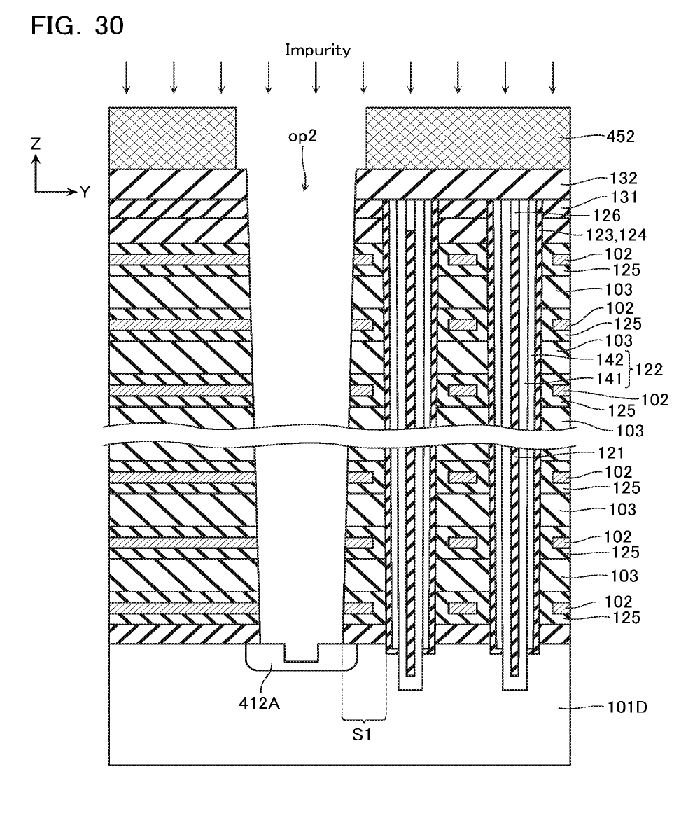

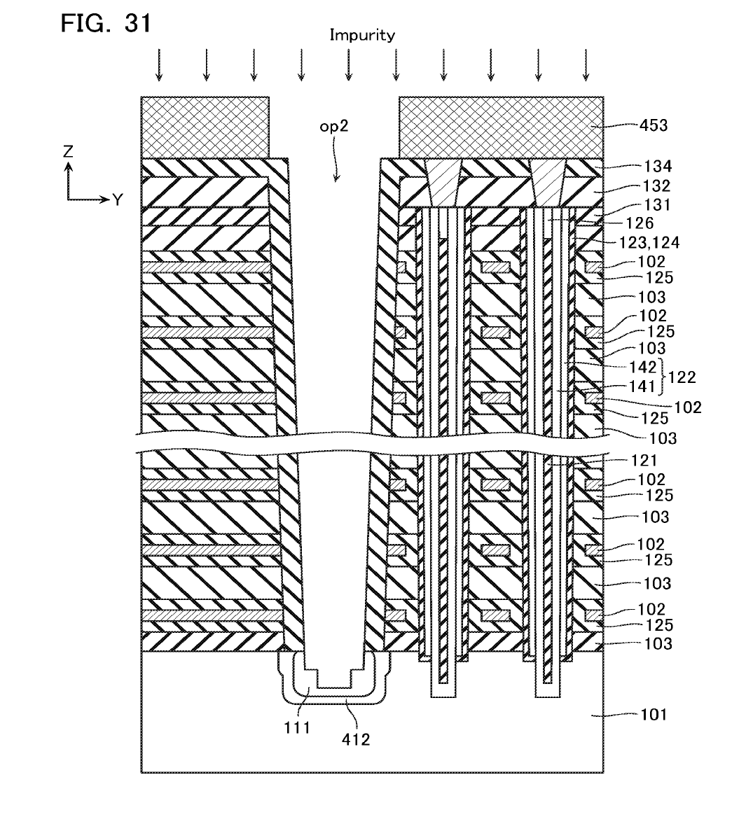

Next, a method of manufacturing a nonvolatile semiconductor memory device according to the second embodiment will be described with reference to FIGS. 29 to 31. FIG. 29 is a flowchart for explaining the same method of manufacturing. FIGS. 30 and 31 are cross-sectional views for explaining the same method of manufacturing. Note that in the description below, portions similar to those of the first embodiment will be assigned with identical reference symbols to those assigned in the first embodiment, and descriptions thereof will be omitted.

As shown in FIG. 29, the method of manufacturing according to the present embodiment is basically performed similarly to the method of manufacturing according to the first embodiment. However, in the same method of manufacturing, the impurity is implanted in step S201 before forming the spacer insulating layer 134 in steps S106 and S107. Moreover, in the same method of manufacturing, the impurity is further implanted in step S108 after forming the spacer insulating layer 134 in steps S106 and S107.

That is, as shown in FIG. 30, in step S201, the impurity is implanted in a substrate 101D via the trench op2, and an impurity diffusion region 412A which will be the low concentration impurity diffusion region 412 is formed. For example, a mask 452 is formed on an upper surface of an insulating layer 132, and an n type impurity such as phosphorus (P) or arsenic (As) is implanted. These impurities diffuse inside the substrate 101 from an exposed surface of the substrate 101. Now, step S201 is performed after broadening the width in the Y direction of the trench op2 instep S104 and before forming the spacer insulating layer 134 in steps S106 and S107. It is therefore possible to implant the impurity from close to the surface S1 facing the lower surface of the conductive layer 102, of the substrate 101 upper surface. As a result, the impurity diffusion region 412A is formed also in part of the above-described surface S1, of the substrate 101 upper surface.

Moreover, as shown in FIG. 31, in step S108, the impurity is implanted in the substrate 101 via the trench op2, and the high concentration impurity diffusion region 111 and the low concentration impurity diffusion region 412 are formed. For example, a mask 453 is formed on an upper surface of a portion positioned above the conductive layer 102, and so on, of the spacer insulating layer 134, and an n type impurity such as phosphorus (P) or arsenic (As) is implanted. The low concentration impurity diffusion region 412 formed at this time is formed integrally with the impurity diffusion region 412A formed in step S201.

### Third Embodiment

[Semiconductor Memory Device]

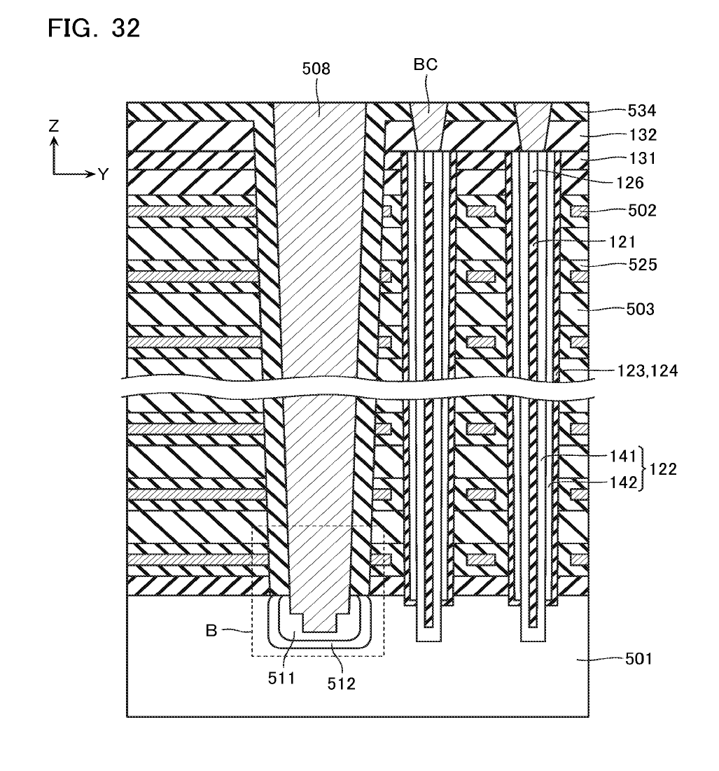

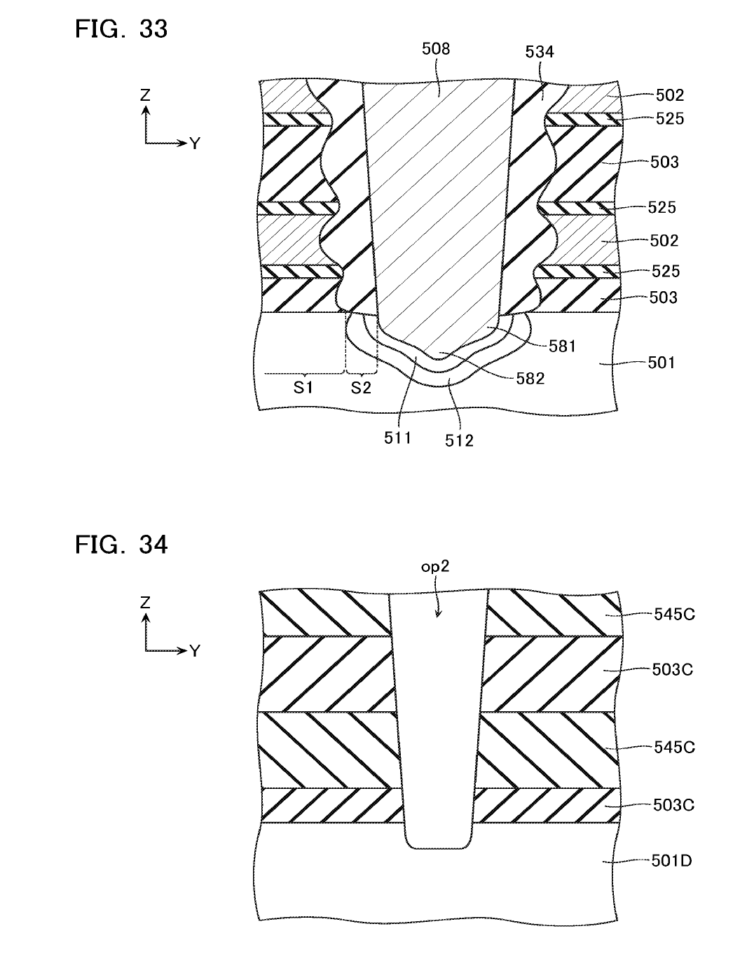

Next, a configuration of a nonvolatile semiconductor memory device according to a third embodiment will be described with reference to FIGS. 32 and 33. FIG. 32 is a cross-sectional view for explaining the configuration of the nonvolatile semiconductor memory device according to the third embodiment. FIG. 33 is a cross-sectional view for explaining the configuration of the same nonvolatile semiconductor memory device, and shows an enlarged view of a portion indicated by B of FIG. 32. Note that in the description below, portions similar to those of the first embodiment will be assigned with identical reference symbols to those assigned in the first embodiment, and descriptions thereof will be omitted.

As shown in FIG. 32, the nonvolatile semiconductor memory device according to the present embodiment is basically configured similarly to the nonvolatile semiconductor memory device according to the first embodiment. Moreover, as shown in FIG. 33, the surface S2 facing a lower surface of a spacer insulating layer 534 and the surface S1 facing a lower surface of a conductive layer 502, of a substrate 501 upper surface are formed continuously.

However, as shown in FIG. 33, in the nonvolatile semiconductor memory device according to the present embodiment, the surface S2 facing the lower surface of the spacer insulating layer 534 and the surface S1 facing the lower surface of the conductive layer 502, of the substrate 501 upper surface are inclined at different angles.

Moreover, as shown in FIG. 33, in the nonvolatile semiconductor memory device according to the present embodiment, a lower end of a conductive layer 508 has formed therein a first portion 581 and a second portion 582, the second portion 582 protruding more downwardly than this first portion 581. Note that both side surfaces in the Y direction of the second portion 582 are provided with a pair of the first portions 581. Moreover, close to a boundary of the first portion 581 and the second portion 582, of a lower surface of the conductive layer 508 is formed in a recessed shape. Therefore, formed at the lower end of the conductive layer 508 are a pair of recessed portions recessed in the Y direction and the Z direction.

Moreover, as shown in FIG. 33, in the nonvolatile semiconductor memory device according to the present embodiment, a recessed portion is formed at a portion facing the spacer insulating layer 534, of an inter-layer insulating layer 503. Furthermore, a side surface in the Y direction facing the inter-layer insulating layer 503 and the conductive layer 502, of the spacer insulating layer 534 is formed along a continuous curved surface so as to protrude at portions facing the inter-layer insulating layer 503 and the conductive layer 502 and recess at a portion facing a block insulating layer 525.

The nonvolatile semiconductor memory device having such a configuration can also prevent occurrence of a leak current between the substrate 501 and the conductive layer 508 and be operated suitably, similarly to the nonvolatile semiconductor memory device according to the first embodiment.

[Method of Manufacturing]

Next, a method of manufacturing a nonvolatile semiconductor memory device according to the third embodiment will be described with reference to FIGS. 34 to 39. FIGS. 34 to 39 are cross-sectional views for explaining the same method of manufacturing. Note that in the description below, portions similar to those of the first embodiment will be assigned with identical reference symbols to those assigned in the first embodiment, and descriptions thereof will be omitted.

The method of manufacturing according to the present embodiment is basically performed similarly to the method of manufacturing according to the first embodiment. That is, as described with reference to FIG. 7, steps from step S101 to step S103 are performed similarly to in the first embodiment. As a result, a structure of the kind shown in FIG. 34 is formed.

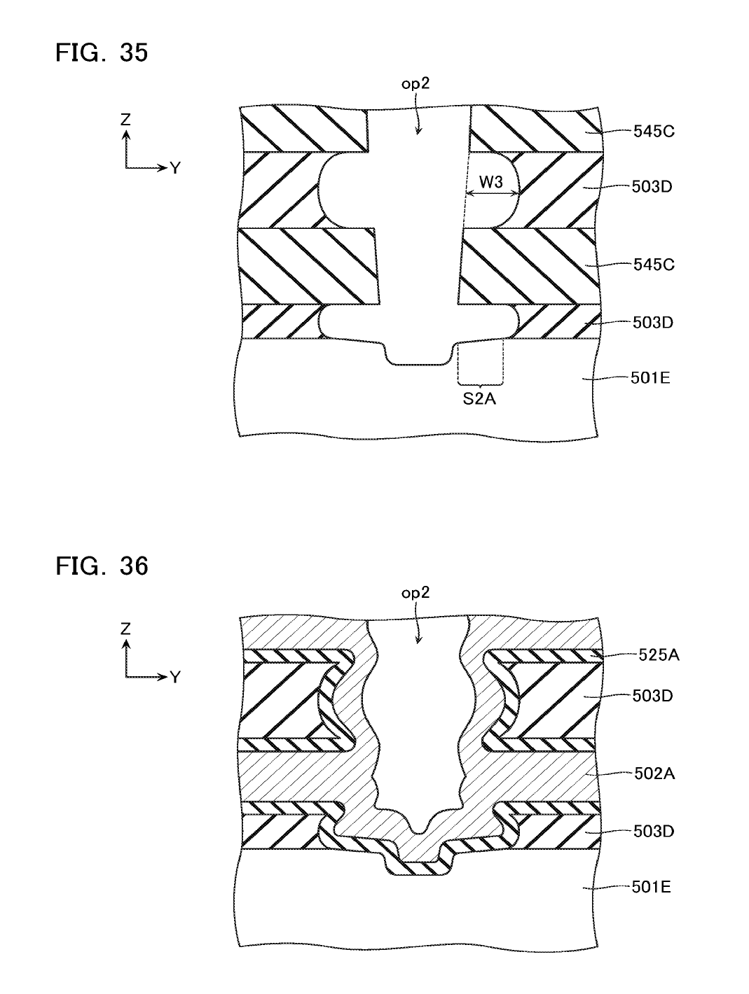

As shown in FIG. 35, in step S104, the width in the Y direction of the trench op2 is broadened. That is, as shown in FIG. 14, part of an insulating layer 503C is removed from the Y direction via the trench op2. For example, in the example shown in FIG. 35, the insulating layer 503C may be removed from the Y direction to an extent of a width W3. Moreover, as shown in FIG. 35, the width W3 may be defined with reference to a central position in the Z direction of the insulating layer 503C, for example. At this time, in the present embodiment, an insulating layer 503C side surface is formed in a recessed shape, and an insulating layer 503D is formed. Moreover, in the present embodiment, part of a substrate 501D upper surface is slightly removed along with removal of a portion contacting the substrate 501D, of the insulating layer 503D, whereby a substrate 501E is formed. As shown in FIG. 35, an upper surface S2A which will be the above-described surface S2, of the substrate 501E may be formed more inclined compared to another portion of the substrate 501E, or may be formed in a curved surface shape.

Next, as shown in FIG. 36, a sacrifice layer 545C is removed. Removal of the sacrifice layer 545C is performed similarly to in the step described with reference to FIG. 15. Moreover, as shown in FIG. 36, an insulating layer 525A which will be the block insulating layer 525 is formed, via the trench op2, on an upper surface, lower surface, and side surface of the inter-layer insulating layer 503D, and on a sidewall of the memory columnar body 105. Moreover, a conductive layer 502A which will be the conductive layer 502 is formed in a portion between the insulating layers 503D adjacent in the stacking direction. At this time, as shown in FIG. 36, the insulating layer 525A and the conductive layer 502A are deposited along a portion formed in a recessed shape, of the insulating layer 503D.

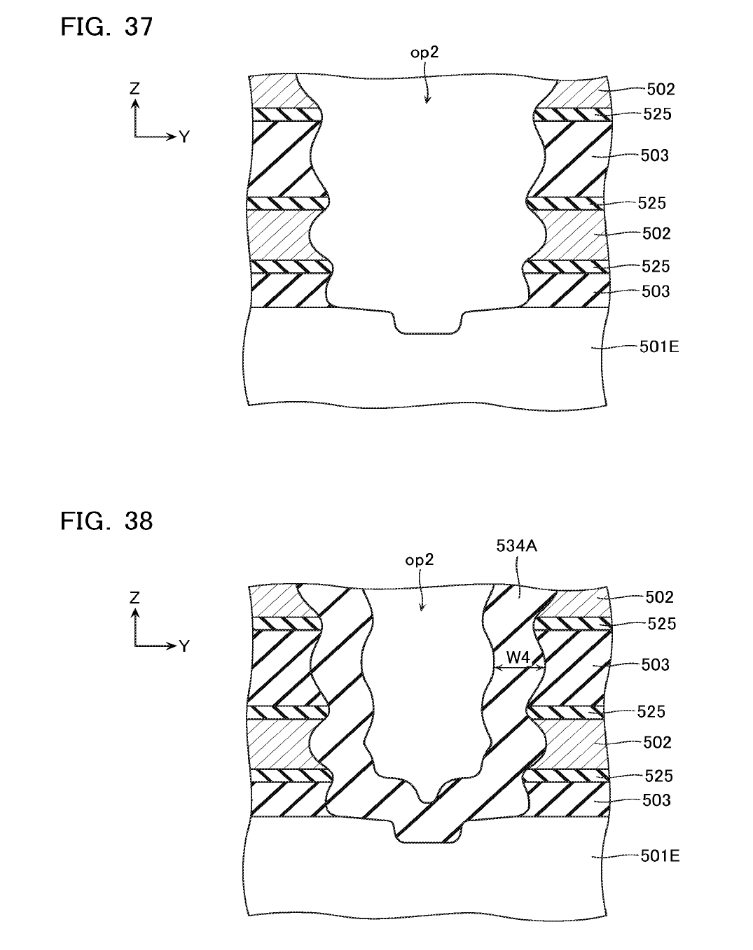

Next, as shown in FIG. 37, portions positioned on the sidewall of the inter-layer insulating layer 503D and portions covering the upper surface of the substrate 501E, of the insulating layer 525A and the conductive layer 502A, are removed. As a result, the block insulating layer 525 and the conductive layer 502 divided in the Z direction are formed. Moreover, in this step, a side surface in the Y direction of the conductive layer 502 is formed in a recessed shape, and a side surface of the block insulating layer 525 is formed in a protruding shape. Furthermore, side surfaces in the Y direction of the inter-layer insulating layer 503, the block insulating layer 525, and the conductive layer 502 are configured as a continuous curved surface formed so as to have a recessed shape at the side surfaces of the inter-layer insulating layer 503 and the conductive layer 502 and to have a protruding shape at the side surface of the block insulating layer 525.

As shown in FIG. 38, in step S106, an insulating layer 534A forming the spacer insulating layer 534 is deposited. The insulating layer 534A is formed from the likes of silicon oxide (SiO₂), for example. Note that a film thickness W4 of the insulating layer 534A may be adjusted so as to be smaller than the width W3, for example, described with reference to FIG. 35.

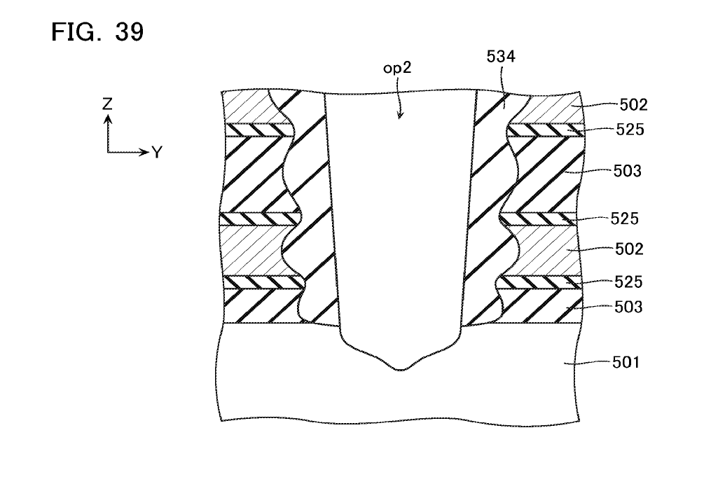

As shown in FIG. 39, in step S107, a portion covering the upper surface of the substrate 501E, of the insulating layer 534A is removed, and the spacer insulating layer 534 is formed. In this step, an upper surface of a portion where a bottom portion of the insulating layer 534A was formed, of the substrate 501E upper surface, is removed, and the substrate 501 is formed.

Then, as described with reference to FIG. 20, the impurity is implanted in the substrate 501 via the trench op2, and a high concentration impurity diffusion region 511 and a low concentration impurity diffusion region 512 are formed. Moreover, as shown in FIG. 33, in step S109, the conductive layer 508 operating as the source contact LI is formed in the trench op2. Then, as shown in FIG. 32, a through hole penetrating the spacer insulating layer 534 and the insulating layer 132 is formed in an upper portion of the memory columnar body 105, and the bit line contact BC is formed therein. As a result, the nonvolatile semiconductor memory device described with reference to FIGS. 32 and 33 is manufactured.

### Others

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A semiconductor memory device, comprising:
a substrate;
a plurality of control gate electrodes stacked on the substrate;
a semiconductor layer having one end thereof connected to the substrate, the semiconductor layer having as its longer direction a direction perpendicular to the substrate, and the semiconductor layer facing the plurality of control gate electrodes;
a charge accumulation layer positioned between the control gate electrode and the semiconductor layer; and
a contact having a lower end thereof connected to the substrate, the contact being adjacent to the plurality of control gate electrodes via a first insulating layer,
a boundary of a first surface that faces a lower surface of the control gate electrode and a second surface that faces a lower surface of the first insulating layer, of an upper surface of the substrate being formed continuously.

2. The semiconductor memory device according to claim 1, wherein
a third surface that faces a lower surface of the contact, of the upper surface of the substrate is positioned more downwardly than the first surface and the second surface of the substrate.

3. The semiconductor memory device according to claim 1, wherein
formed in the lower end of the contact is a protruding portion that protrudes more downwardly compared to another portion of the lower end.

4. The semiconductor memory device according to claim 1, wherein
formed in the lower end of the contact are a pair of recessed portions.

5. The semiconductor memory device according to claim 1, wherein
a contact surface with the contact, of the substrate is provided with an impurity diffusion layer, and
the impurity diffusion layer
covers a contact surface with the substrate, of the contact, and
covers at least part of the lower surface of the first insulating layer.

6. The semiconductor memory device according to claim 5, wherein
the impurity diffusion layer is formed downward of the boundary of the first surface and the second surface, of the substrate.

7. The semiconductor memory device according to claim 1, further comprising
an inter-layer insulating layer positioned between the plurality of control gate electrodes,
wherein a surface facing the first insulating layer, of the inter-layer insulating layer has a recessed portion formed therein.

8. A method of manufacturing a semiconductor memory device, comprising:
alternately stacking a plurality of first insulating layers and first layers on a substrate to form a stacked body;
forming a through hole, the through hole penetrating the stacked body;
forming a semiconductor layer inside the through hole, the semiconductor layer having as its longer direction a direction perpendicular to the substrate, and the semiconductor layer facing the plurality of first insulating layers and first layers;
forming an opening, the opening penetrating the stacked body;
removing part of the stacked body to broaden a width in a first direction parallel to the substrate, of the opening;
forming a second insulating layer on a sidewall exposed in the opening, of the stacked body;
implanting an impurity in a portion exposed in the opening, of the substrate; and
forming a contact on the portion exposed in the opening, of the substrate.

9. The method of manufacturing a semiconductor memory device according to claim 8, comprising:
after forming the opening and before forming the contact,
removing the first layer; and
forming a first conductive layer between the stacked first insulating layers, the first conductive layer facing the semiconductor layer.

10. The method of manufacturing a semiconductor memory device according to claim 8, comprising
after forming the opening, removing part of the first insulating layer to broaden the width in the first direction of the opening.

11. The method of manufacturing a semiconductor memory device according to claim 8, wherein
when broadening the width in the first direction of the opening, a removed portion of the stacked body is removed faster than the substrate.

12. The method of manufacturing a semiconductor memory device according to claim 8, wherein
when broadening the width in the first direction of the opening, a width of a removed portion of the stacked body is larger than a width of the second insulating layer.

13. The method of manufacturing a semiconductor memory device according to claim 8, comprising:
when forming the second insulating layer on the sidewall exposed in the opening, of the stacked body,
depositing a second insulating layer formation layer forming the second insulating layer, on the sidewall exposed in the opening, of the stacked body and on an upper surface exposed in the opening, of the substrate; and
selectively removing a portion covering the upper surface of the substrate, of the second insulating layer formation layer.
